(19) United States
(12) Patent Application Publication
(10) Pub. No.: US 2025/0306089 A1
(43) Pub. Date: Oct. 2, 2025

(54) ELECTRO-CONDUCTIVE CONTACT PIN AND INSPECTION DEVICE INCLUDING SAME

(71) Applicant: POINT ENGINEERING CO., LTD., Chungcheongnam-do (KR)

(72) Inventors: Bum Mo AHN, Gyeonggi-do (KR); Seung Ho PARK, Gyeonggi-do (KR); Chang Hee HONG, Gyeonggi-do (KR)

(73) Assignee: POINT ENGINEERING CO., LTD., Chungcheongnam-do (KR)

(21) Appl. No.: 18/863,989

(22) PCT Filed: May 2, 2023
(86) PCT No.: PCT/KR2023/005971

§ 371 Date: Nov. 7, 2024

(30) Foreign Application Priority Data
May 9, 2022 (KR) 10-2022-0056669

(51) Int. Cl. G01R 31/28; G01R 1/067

(52) U.S. Cl. CPC G01R 31/2887; G01R 1/06716; G01R 1/06738; G01R 31/2896

(57) ABSTRACT

The present invention provides an electro-conductive contact pin which can implement a narrow-pitch and an inspection device including same. Furthermore, the present invention provides an electro-conductive contact pin which uses a guide housing formed to have consistent thickness overall, including a portion corresponding to a lower part of an interference member and prevents damage due to interference with the interference member, and an inspection device including same.

### CROSS-REFERENCE TO RELATED APPLICATION

This application is a 371 of international application of PCT application serial no. PCT/KR2023/005971, filed on May 2, 2023, which claims the priority benefit of Korea application no. 10-2022-0056669, filed on May 9, 2022. The entirety of each of the above mentioned patent applications is hereby incorporated by reference herein and made a part of this specification.

### TECHNICAL FIELD

The present disclosure relates to an electro-conductive contact pin and an inspection device including the same.

### BACKGROUND ART

A test for electrical characteristics of a device is performed by approaching an inspection object (semiconductor wafer or semiconductor package) to an inspection device having a plurality of electro-conductive contact pins and then bringing the respective electro-conductive contact pins into contact with corresponding external terminals (solder balls or bumps) on the inspection object. Examples of inspection devices include, but are not limited to, probe cards or test sockets.

Conventional test sockets include a pogo-type socket and a rubber-type socket.

An electro-conductive pin (hereinafter contact referred to as a “pogo-type socket pin”) used in the pogo-type test socket includes a pin portion and a barrel accommodating the pin portion. The pin portion is provided with a spring member between plungers at opposite ends of the pin portion to enable application of required contact pressure and shock absorption at a contact position. In order for the pin portion to slide within the barrel, a gap exists between an outer surface of the pin portion and an inner surface of the barrel. However, since the pogo-type socket pin is used by separately manufacturing the barrel and the pin portion and then assembling them together, the gap between the outer surface of the pin portion and the inner surface of the barrel is increased more than necessary, so it is impossible to precisely manage the gap. Therefore, electrical signals are lost and distorted in the process of being transferred to the barrel via the opposite plungers, causing a problem in that contact stability is not constant.

Meanwhile, an electro-conductive contact pin (hereinafter referred to as a “rubber-type socket pin”) used in the rubber-type test socket has a structure in which conductive particles are disposed inside a silicon rubber made of a rubber material. When stress is applied by placing an inspection object (e.g., a semiconductor package) and closing the socket, conductive particles strongly press each other and increase conductivity, making the particles electrically connected. However, the rubber-type socket pin has a problem in that contact stability is secured only when the socket pin is pressed with an excessive pressing force.

With the advancement and high integration of semiconductor technology, the pitch of the external terminals of the inspection object has become narrower.

In the case of the rubber-type socket pin, the socket pin is produced by preparing a molding material in which conductive particles are distributed in a fluid elastic material, inserting material into the molding a predetermined mold, and applying a magnetic field in the thickness direction to arrange the conductive particles in the thickness direction. Due to this manufacturing technique, when the distance between magnetic fields is narrowed, the conductive particles are irregularly oriented and a signal flows in the plane direction. Thus, the conventional rubber-type socket pin has limitations in responding to the trend toward narrow pitch technology. In addition, since the pogo-type socket pin is used by separately manufacturing the barrel and the pin portion and then assembling them together, it is difficult to manufacture the socket pin in a small size. Thus, the pogo-type socket pin also has limitations in responding to the trend toward narrow pitch technology.

The narrow pitch trend requires the spacing between pins to be also reduced. However, the conventional rubber-type socket pin and the pogo-type socket pin are reaching their limits in terms of reducing their size.

FIGS. 1 to 4 are views illustrating the technology served as the background for the present disclosure. The technology served as the background for the present disclosure described below is a non-public internal technology.

The technology served as the background for the present disclosure is to construct an inspection device 1 by inserting an electro-conductive contact pin 10 manufactured by an MEMS process into a through-hole of a guide housing 3 and inspect a semiconductor package 8. The inspection device 1 includes an insert 5 in which an inspection object (e.g., semiconductor package 8) is received, the guide housing 3 in which the electro-conductive contact pin 10 is inserted and installed, and a pusher 4 for pressurizing the semiconductor package 8.

A plurality of electro-conductive contact pins 10 are installed in the guide housing 3. The insert 5 receives the semiconductor package 8 so that testing is performed on the semiconductor package 8 in a stable state. An insert film 9 having holes provided to guide terminals 8-1 of the semiconductor package 8 is installed at a lower part of the insert 5. The insert film 9 is provided between the semiconductor package 8 and the electro-conductive contact pins 10. When inspecting the semiconductor package 8, the insert film 9 accurately guides a contact position of the terminals 8-1 of the semiconductor package 8 by allowing the terminals of the semiconductor package to be inserted into the holes provided in the insert film 9. The pusher 4 serves to pressurize the semiconductor package 8 seated in a receiving portion of the insert 5 at a constant pressure. The semiconductor package 8 pressurized by the pusher 4 may be electrically connected to pads 6-1 of a circuit board 6 through the electro-conductive contact pins 10 installed in the guide housing 3.

At the lower part of the insert 5, a fixing pin 2-1 for fixing the insert film 9 to the insert 5 and an alignment key 2-2 for precisely adjusting the position of the insert film 9 are provided. The fixing pin 2-1 and the alignment key 2-2 are provided to protrude downward from the lower part of the insert 5. In accordance with the recent narrow pitch trend, the separation distance between the terminals 8-1 of the semiconductor package 8 has become smaller, and the size of the terminals 8-1 has also become smaller. In response to this, the fixing pin 2-1 and the alignment key 2-2 are provided in a form that protrudes further downward than the terminals 8-1 of the semiconductor package 8.

An inspection process using the inspection device 1 as above will be described. First, as illustrated in FIG. 1, the semiconductor package 8 is seated on the insert 5. Then, an upper surface of the semiconductor package 8 is pressurized toward the circuit board 6 using the pusher 4. At this time, as illustrated in FIG. 2, it was found that the fixing pin 2-1 and the alignment key 2-2 protruding from the lower part of the insert 5 interfered with the guide housing 3 and collide with it, thereby deforming the guide housing 3 and, as a result, pressurizing and deforming the electro-conductive contact pins 10. This caused the guide housing 3 or the electro-conductive contact pins 10 to become deformed or damaged, which hindered proper inspection or reduced the durability of the inspection device 1.

Meanwhile, there is also a structure that supports the semiconductor package 8 without the insert film 9. A support protrusion (not illustrated) that supports the edge of the semiconductor package 8 may be provided at the lower part of the insert 5 so that the semiconductor package 8 is hung on the support protrusion, thereby allowing the semiconductor package 8 to be supported on the insert 5. However, since the support protrusion is also provided to protrude from the lower part of the insert 5, the same problem occurs in that the support protrusion collides with the guide housing 3 and deforms the guide housing 3 and the electro-conductive contact pins 10. This causes damage to the guide housing 3 or the electro-conductive contact pins 10, resulting in a reduction in the durability of the inspection device 1.

Since such interference members, i.e., the fixing pin 2-1, the alignment key 2-2, and the support protrusion (not illustrated), are configured to protrude from the lower part of the insert 5, a problem arises in that the interference members interfere with or collide with the guide housing 3.

To solve this interference problem, as illustrated in FIG. 3A, a method of thinning a part of the guide housing 3 corresponding to the lower part of the interference members may be considered. Alternatively, as illustrated in FIG. 3B, a method of cutting and removing away a part of the guide housing 3 corresponding to the lower part of the interference member may be considered. However, the above solutions has limitations because they cause the problem of partially weakening the strength of the guide housing 3, resulting in local damage or breakage of the guide housing 3.

### DOCUMENTS OF RELATED ART

### Patent Documents

(Patent Document 1) Korean Patent No. 10-0659944

(Patent Document 2) Korean Patent No. 10-0952712

### DISCLOSURE

### Technical Problem

Accordingly, the present disclosure has been made keeping in mind the above problems occurring in the related art, and one objective of the present disclosure is to provide an electro-conductive contact pin capable of implementing a narrow pitch and an inspection device including the same.

Another objective of the present disclosure is to provide an electro-conductive contact pin and an inspection device including the same, in which the electro-conductive contact pin uses a guide housing formed with a uniform overall thickness including a part corresponding to a lower part of an interference member, and prevents the guide housing from being damaged due to interference with the interference member.

### Technical Solution

In order to accomplish the above objectives, the present disclosure provides an inspection device, including: an insert having a receiving portion configured to receive a semiconductor package; an interference member provided at a lower part of the insert, and protruding further downward than a terminal of the semiconductor package while the semiconductor package is received in the receiving portion of the insert; a guide housing formed with a uniform overall thickness including a part corresponding to a position of the interference member; and an electro-conductive contact pin installed in the guide housing. A protrusion length of the electro-conductive contact pin protruding upward from an upper surface of the guide housing may be longer than a protrusion length of the interference member protruding downward from a lower end of the terminal.

In addition, in a stroke completion step where the terminal of the semiconductor package is further lowered to a stroke limit value after contact with the electro-conductive contact pin, a third separation distance may be formed so that the interference member does not make contact with the guide housing.

In addition, in a stroke completion step where the terminal of the semiconductor package is further lowered to a stroke limit value after contact with the electro-conductive contact pin, the electro-conductive contact pin may be allowed to be further compressed even when the interference member is brought into contact with the guide housing.

In addition, the electro-conductive contact pin may include: a first connection portion connected to the terminal of the semiconductor package; a second connection portion connected to a circuit board; a support portion facing an inner wall of the guide housing and extending in a length direction; an elastic portion connected to at least one of the first connection portion and the second connection portion and configured to be elastically deformable along the length direction; and a connecting portion connecting the elastic portion to the support portion.

In addition, the first connection portion may include a first contact portion configured to be brought into contact with the terminal; and a first flange extending downward from the first contact portion and provided between the elastic portion and the support portion.

In addition, the first flange may be brought into contact with an inner surface of the support portion as the elastic portion is compressed, thereby forming a current path.

In addition, the support portion may include: a first support portion located at a first side of the electro-conductive contact pin; and a second support portion located at a second side of the electro-conductive contact pin. A dimension of the first contact portion in a width direction may be smaller than a dimension between the first support portion and the second support portion, and the first flange may be located within a region between the first support portion and the second support portion.

Meanwhile, according to another aspect of the present disclosure, there is provided an inspection device, including: an insert having a receiving portion configured to receive a semiconductor package; an interference member protruding further downward than a terminal of the semiconductor package while the semiconductor package is received in the receiving portion of the insert; a guide housing formed with a uniform overall thickness including a part corresponding to a position of the interference member; and an electro-conductive contact pin installed in the guide housing. In a pre-pusher pressurization step before pressurizing the semiconductor package toward the electro-conductive contact pin, the terminal of the semiconductor package may not make contact with the electro-conductive contact pin.

In addition, in a contact step where the semiconductor package is pressurized toward the electro-conductive contact pin so that the terminal of the semiconductor package is brought into contact with the electro-conductive contact pin, a second separation distance may be formed so that the interference member does not make contact with the guide housing.

In addition, in a stroke completion step where the terminal of the semiconductor package is further lowered to a stroke limit value after contact with the electro-conductive contact pin, a third separation distance may be formed so that the interference member does not make contact with the guide housing.

In addition, in a stroke completion step where the terminal of the semiconductor package is further lowered to a stroke limit value after contact with the electro-conductive contact pin, a third separation distance may be formed so that the interference member does not make contact with the guide housing, and a difference between a first separation distance and the third separation distance may correspond to the set stroke limit value.

In addition, even when the terminal of the semiconductor package is further lowered beyond the stroke limit value until the electro-conductive contact pin is compressed to a maximum extent, a fourth separation distance may be formed so that the interference member does not make contact with the guide housing.

In addition, the electro-conductive contact pin may include an elastic portion formed by alternately connecting a plurality of straight portions and a plurality of curved portions. Even when the terminal of the semiconductor package is further lowered beyond the stroke limit value until the electro-conductive contact pin is compressed to the maximum extent, the straight portions adjacent in upper and lower directions may not make contact with each other. Meanwhile, according to another aspect of the present

disclosure, there is provided an electro-conductive contact pin, including: a first connection portion having a first flange extending downward and configured to be brought into contact with a terminal of a semiconductor package; a second connection portion configured to be brought into contact with a circuit board; an elastic portion configured to be elastically deformed so that the first connection portion and the second connection portion are displaced relative to each other; and a stopper configured to be brought into contact with a lower end of the first flange when the first connection portion is moved downward. The first flange may be brought into contact with the stopper before the elastic portion reaches its maximum compression state.

In addition, the electro-conductive contact pin may further include: a support portion extending in a length direction; and a connecting portion connecting the elastic portion to the support portion. The connecting portion may serve as the stopper.

In addition, the elastic portion may be formed by alternately connecting a plurality of straight portions and a plurality of curved portions. The straight portions adjacent in upper and lower directions may not make contact with each other while the first flange is in contact with the stopper.

Meanwhile, according to another aspect of the present disclosure, there is provided an inspection device, including: a guide housing formed with a uniform overall thickness; and an electro-conductive contact pin installed in the guide housing. The electro-conductive contact pin may include: a first connection portion connected to a terminal of a semiconductor package; a second connection portion connected to a circuit board; a support portion facing an inner wall of the guide housing and extending in a length direction; an elastic portion connected to at least one of the first connection portion and the second connection portion and configured to be elastically deformable along the length direction; and a connecting portion connecting the elastic portion to the support portion. A protrusion length of the first connection portion protruding from an upper surface of the guide housing may be longer than a protrusion of the second connection portion protruding from a lower surface of the guide housing. The first connection portion and the second connection portion may be displaceable in a vertical direction, and a displacement range of the first connection portion may be longer than that of the second connection portion. At least one of the first connection portion and the second connection portion may be brought into contact with the support portion during displacement to form a current path.

In addition, the guide housing may be made of a polyimide material.

In addition, the first connection portion may include: a first contact portion configured to be brought into contact with the terminal; and a first flange extending downward from the first contact portion and provided between the elastic portion and the support portion. Downward displacement of the first flange may cause a lower end of the first flange to be brought into contact with the connecting portion, thereby stopping further downward movement of the first contact portion.

### Advantageous Effects

The present disclosure can provide an electro-conductive contact pin capable of implementing a narrow pitch and an inspection device including the same.

In addition, the present disclosure can provide an electro-conductive contact pin and an inspection device including the same, in which the electro-conductive contact pin uses a guide housing formed with a uniform overall thickness including a part corresponding to a lower part of an interference member, and prevents the guide housing from being damaged due to interference with the interference member.

### DESCRIPTION OF DRAWINGS

FIG. 1 is a view illustrating the technology served as the background for the present disclosure, illustrating a non-pressurizing state of a pusher.

FIG. 2 is a view illustrating the technology served as the background for the present disclosure, illustrating a pressurizing state of the pusher.

FIG. 3A is a view illustrating the technology served as the background for the present disclosure, illustrating a part of a guide housing made thin.

FIG. 3B is a view illustrating the technology served as the background for the present disclosure, illustrating a part of the guide housing cut away.

FIG. 4 is a front view illustrating an electro-conductive contact pin according to a preferred embodiment of the present disclosure.

FIG. 5 is a perspective view illustrating the electro-conductive contact pin according to the preferred embodiment of the present disclosure.

FIGS. 6A to 6D are views illustrating a method of manufacturing the electro-conductive contact pin according to the preferred embodiment of the present disclosure.

FIG. 7 is a view illustrating a side surface of the electro-conductive contact pin according to the preferred embodiment of the present disclosure.

FIG. 8 is a view illustrating a guide housing into which the electro-conductive contact pin is inserted according to the preferred embodiment of the present disclosure.

FIG. 9 is a view illustrating an inspection device according to the preferred embodiment of the present disclosure, illustrating a pre-pusher pressurization step before a semiconductor package is seated on an insert and then pressurized by the pusher.

FIG. 10 is an enlarged view of a part of the inspection device according to the preferred embodiment of the present disclosure, illustrating the pre-pusher pressurization step before the semiconductor package is seated on the insert and then pressurized by the pusher.

FIGS. 11 and 12 are enlarged views of the portion of the inspection device according to the preferred embodiment of the present disclosure, illustrating a contact step in which a terminal of the semiconductor package is brought into contact with the electro-conductive contact pin after pressurization of the pusher.

FIG. 13 is an enlarged view of the portion of the inspection device according to the preferred embodiment of the present disclosure, illustrating a stroke completion step in which the semiconductor package is lowered to a stroke limit value by pressurization of the pusher.

FIG. 14 is an enlarged view of the portion of the inspection device according to the preferred embodiment of the present disclosure, illustrating a maximum compression step in which the electro-conductive contact pin is compressed to the maximum possible extent.

FIGS. 15A to 15C are views illustrating a comparison pressurization step before the of the pre-pusher semiconductor package is seated on the insert and then pressurized by the pusher between the preferred embodiment of the present disclosure, the technology served as the background for the present disclosure, and a conventional rubber-type test socket, in which FIG. 15A is a view illustrating the preferred embodiment of the present disclosure, FIG. 15B is a view illustrating the technology served as the background for the present disclosure, and FIG. 15C is a view illustrating the conventional rubber-type test socket.

FIGS. 16A to 16C are views illustrating a comparison of the stroke completion step in which the semiconductor package is lowered to the stroke limit value by pressurization of the pusher between the preferred embodiment of the present disclosure, the technology served as the background for the present disclosure, and the conventional rubber-type test socket, in which FIG. 16A is a view illustrating the preferred embodiment of the present disclosure, FIG. 16B is a view illustrating the technology served as the background for the present disclosure, and FIG. 16C is a view illustrating the conventional rubber-type test socket.

FIG. 17 is a view illustrating a case where a terminal of the semiconductor package is lowered eccentrically rather than in a proper position in the positional relationship with the electro-conductive contact pin according to the preferred embodiment of the present disclosure.

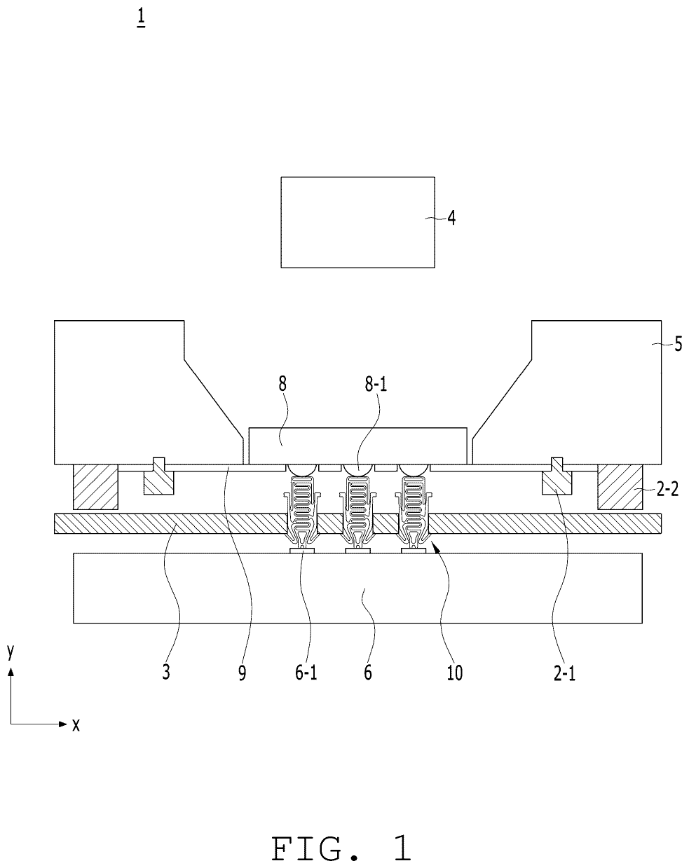

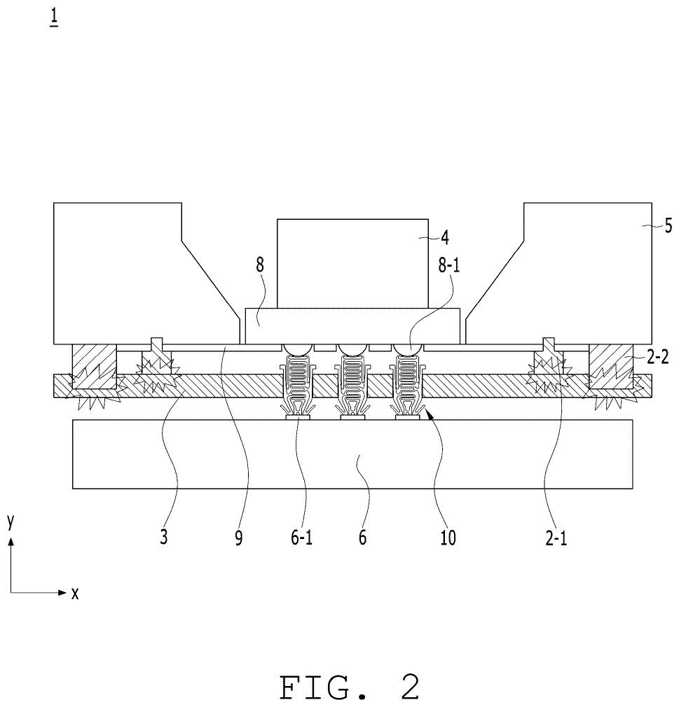

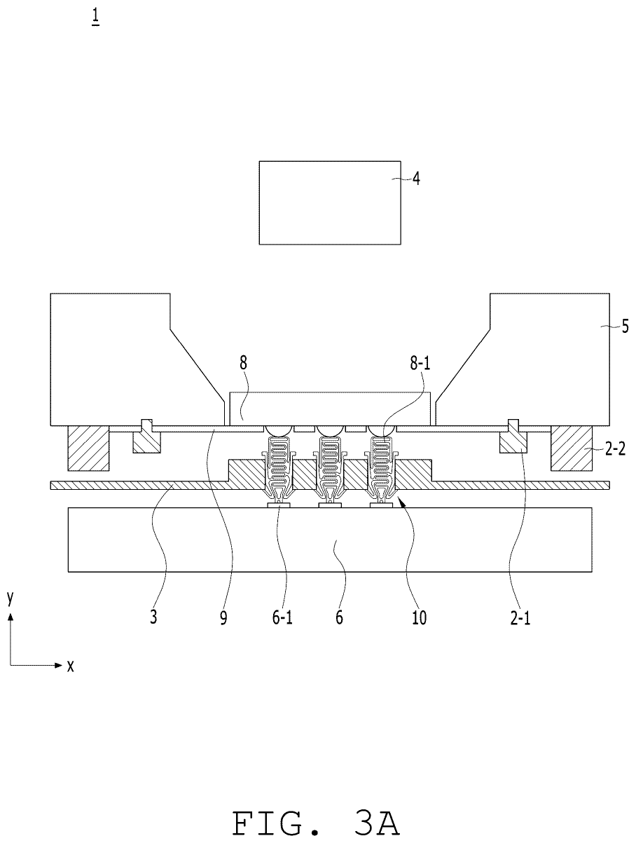

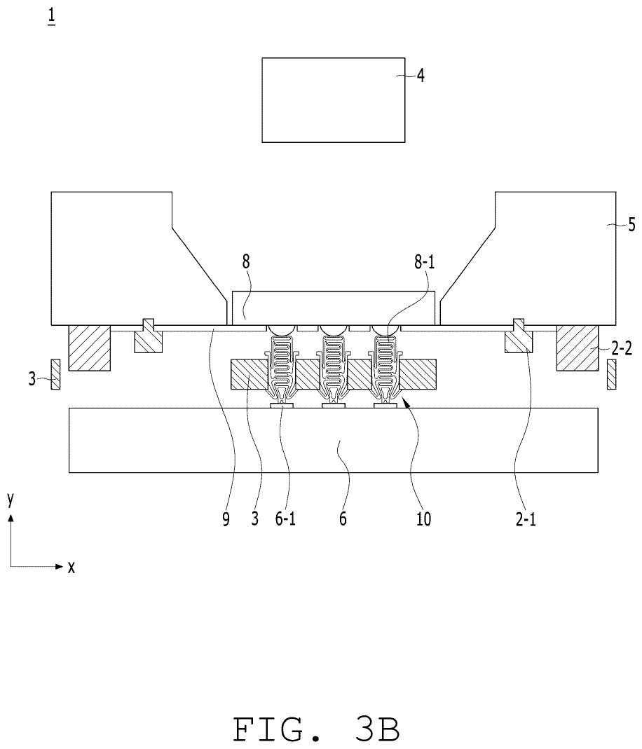

### MODE FOR INVENTION

Contents of the description below merely exemplify the principle of the present disclosure. Therefore, those of ordinary skill in the art may implement the theory of the present disclosure and invent various apparatuses which are included within the concept and the scope of the present disclosure even though it is not clearly explained or illustrated in the description. Furthermore, all conditional terms and embodiments listed in this description are, in principle, clearly intended for the purpose of understanding the concept of the present disclosure, and one should understand that the present disclosure is not limited to the exemplary embodiments and the conditions.

The above described objectives, features, and advantages will be more apparent through the following detailed description related to the accompanying drawings, and thus those of ordinary skill in the art may easily implement the technical spirit of the present disclosure.

The embodiments of the present disclosure are described with reference to sectional views and/or perspective views which schematically illustrate ideal embodiments of the present disclosure. For explicit and convenient description of the technical content, sizes or thicknesses of films and regions in the figures may be exaggerated. As such, variations from the shapes of the illustrations as a result, for example, of manufacturing techniques and/or tolerances, are to be expected. Further, a limited number of molded articles are shown in the drawings as an example. Thus, the embodiments should not be construed as limited to the particular shapes of regions illustrated herein but are to include deviations in shapes that result, for example, from manufacturing.

Hereinafter, preferred embodiments of the present disclosure will be described in detail with reference to the accompanying drawings.

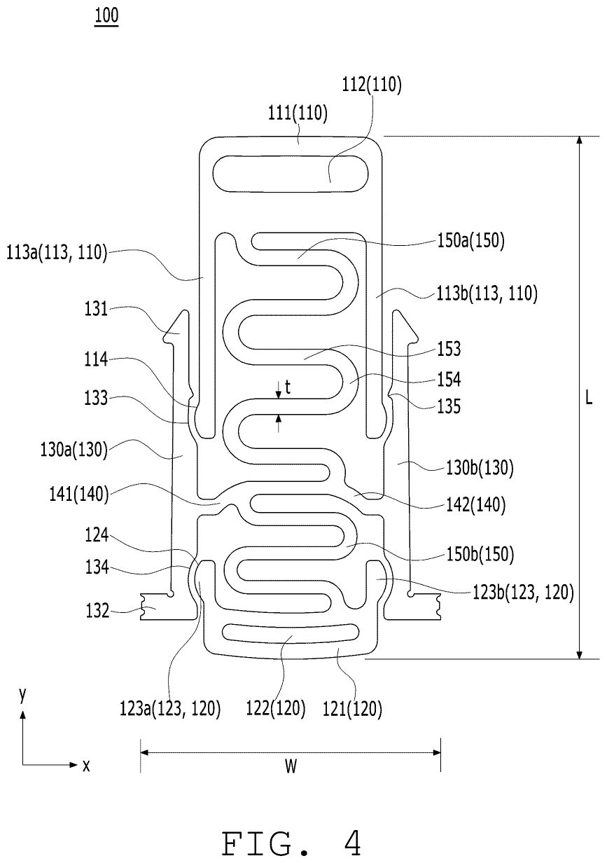

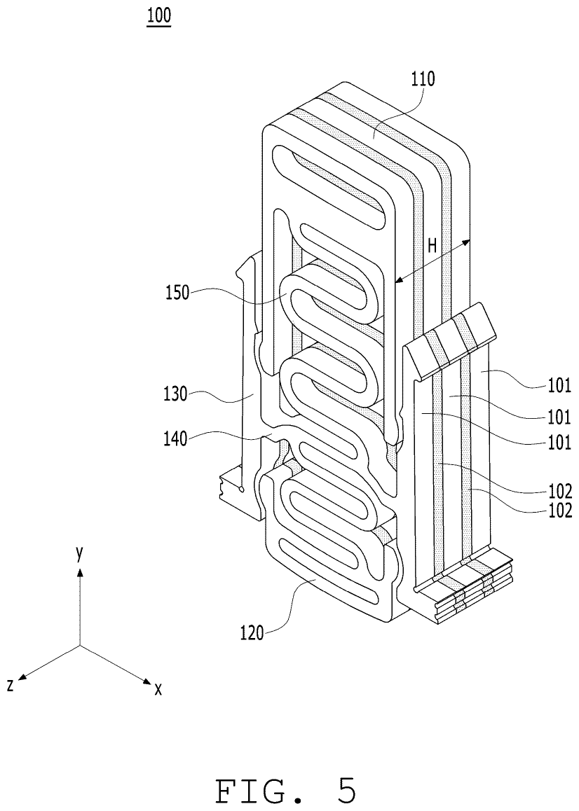

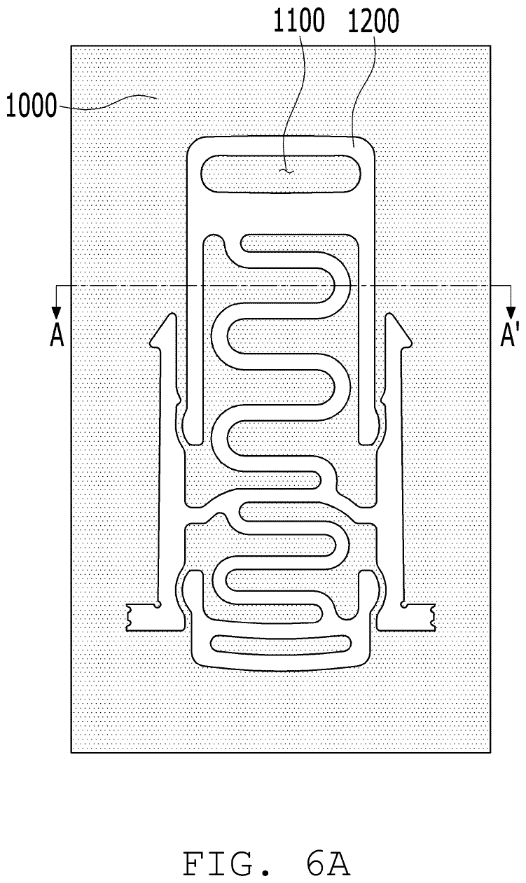

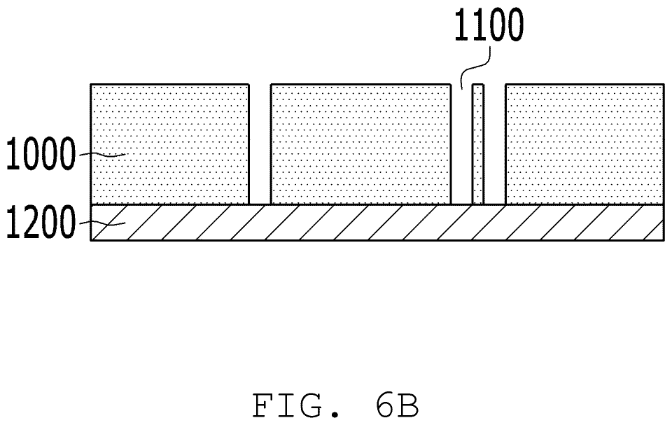

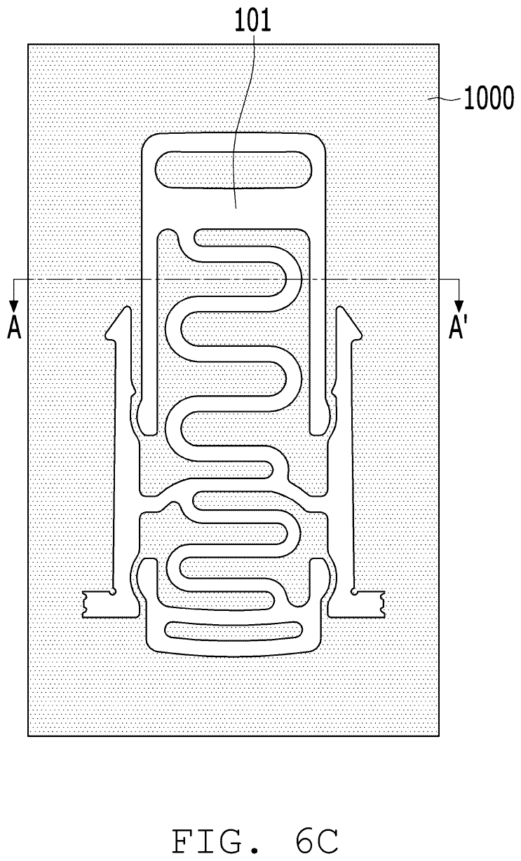

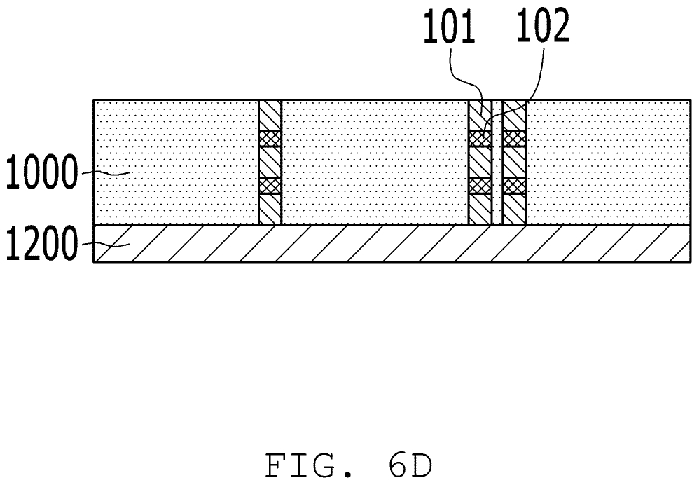

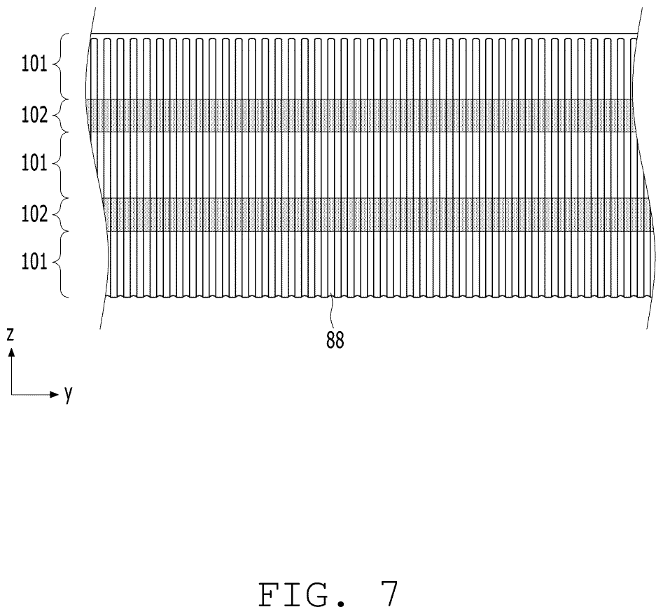

Hereinafter, an electro-conductive contact pin 100 according to a preferred embodiment of the present disclosure will be described with reference to FIGS. 4 to 7. FIG. 4 is a front view illustrating the electro-pin 100 according to the preferred conductive contact embodiment of the present disclosure. FIG. 5 is a perspective view illustrating the electro-conductive contact pin 100 according to the preferred embodiment of the present disclosure. FIGS. 6A to 6D are views illustrating a method of manufacturing the electro-conductive contact pin 100 according to the preferred embodiment of the present disclosure. FIG. 7 is a view illustrating a side surface of the electro-conductive contact pin 100 according to the preferred embodiment of the present disclosure.

The electro-conductive contact pin 100 according to the preferred embodiment of the present disclosure is provided in an inspection device 11 and is used to transmit electrical signals by making electrical and physical contact with an inspection object. The inspection device 11 may be an inspection device used in a semiconductor manufacturing process, for example, a probe card or a test socket. The inspection device 11 includes the electro-conductive contact pin and a guide housing 30 having a through-hole 31 for receiving the electro-conductive contact pin 100. The electro-conductive contact pin 100 may be a probe pin provided in the probe card or a socket pin provided in the test socket. In the following, the socket pin will be exemplified and described as an example of the electro-conductive contact pin 100. However, the electro-conductive contact pin 100 according to the preferred embodiment of the present disclosure is not limited thereto and includes any pin for checking whether the inspection object is defective by applying electricity.

In the following description, the width direction of the electro-conductive contact pin 100 refers to the ±x direction indicated in the drawings, the length direction of the electro-conductive contact pin 100 refers to the ±y direction indicated in the drawings, and the thickness direction of the electro-conductive contact pin 100 refers to the ±z direction indicated in the drawings.

The electro-conductive contact pin 100 has an overall length L in the length direction (±y direction), an overall thickness H in the thickness direction (±z direction) orthogonal to the length direction, and an overall width W in the width direction (±x direction) orthogonal to the length direction.

The electro-conductive contact pin 100 includes a first connection portion 110, a second connection portion 120, a support portion 130 extending in the length direction, an elastic portion 150 connected to the first connection portion 110 and the second connection portion 120 and elastically deformable along the length direction, and a connecting portion 140 connecting the elastic portion 150 to the support portion 130.

The first connection portion 110, the second connection portion 120, the support portion 130, the connecting portion 140, and the elastic portion 150 are provided as a single body. The first connection portion 110, the second connection portion 120, the support portion 130, the connecting portion 140, and the elastic portion 150 are manufactured simultaneously through a plating process. As described later, since the electro-conductive contact pin 100 is formed using a mold 1000 having an inner space 1100 by filling the inner space 1100 with a metal material through electroplating, The first connection portion 110, the second connection portion 120, the support portion 130, the connecting portion 140, and the elastic portion 150 are connected to each other and manufactured as a single body. A conventional pogo-type socket pin is provided by separately manufacturing a barrel and a pin portion and then assembling them. However, the electro-conductive contact pin 100 according to the preferred embodiment has a structural difference in that it is provided as a single body by simultaneously manufacturing the first connection portion 110, the second connection portion 120, the support portion 130, the connecting portion 140, and the elastic portion 150 through the plating process. In response to the trend toward a narrow pitch, it is possible to manufacture electro-conductive contact pins 100 in a smaller size and to arrange electro-conductive contact pins 100 more densely.

The electro-conductive contact pin 100 has a uniform cross-sectional shape in the thickness direction (±z direction). In other words, the uniform cross-sectional shape on the x-y plane is formed by extending in the thickness direction (±z direction).

The electro-conductive contact pin 100 is formed by stacking a plurality of different metal layers in the thickness direction (±z direction). The plurality of different metal layers include a first metal layer 101 and a second metal layer 102.

The first metal layer 101 may be made of a metal having relatively high wear resistance compared to the second metal layer 102, preferably a metal selected from: the group consisting of rhodium (Rh), platinum (Pt), iridium (Ir), palladium (Pd), nickel (Ni), manganese (Mn), tungsten (W), phosphorus (Ph), and an alloy of these metals; the group consisting of a palladium-cobalt (PdCo) alloy and a palladium-nickel (PdNi) alloy; or the group consisting of a nickel-phosphor (NiPh) alloy, a nickel-manganese (NiMn) alloy, a nickel-cobalt (NiCo) alloy, and a nickel-tungsten (NiW) alloy. The second metal layer 102 may be made of a metal having relatively high electrical conductivity compared to the first metal layer 102, preferably a metal selected from the group consisting of copper (Cu), silver (Ag), gold (Au), and an alloy of these metals. However, the present disclosure is not limited thereto.

The first metal layer 101 is provided on each of a lower surface and an upper surface of the electro-conductive contact pin 100 in the thickness direction (±z direction), and the second metal layer 102 is provided between the respective first metal layers 101. For example, the electro-conductive contact pin 100 may be provided by sequentially stacking the first metal layer 101, the second metal layer 102, and the first metal layer 101 in the thickness direction (±z direction), and the number of stacked layers may be at least three.

The first connection portion 110 includes a first contact portion 111 brought into contact with a terminal 85 of a semiconductor package 80, and a first flange 113 extending downward from the first contact portion 111. The first flange 113 is provided between the elastic portion 150 and the support portion 130 and is provided to cover at least a part of the elastic portion 150 from outside the elastic portion. When the elastic portion 150 is elastically deformed, the first contact portion 111 and the first flange 113 are moved integrally.

The first contact portion 110 is a portion that is brought into contact with the terminal 85 of the semiconductor package 80.

The first contact portion 111 has a first hollow 112 so that a contact surface of the first contact portion 111 is more easily deformed by the pressure of the semiconductor package 80. An upper surface of the first contact portion 111 located above the first hollow 112 is brought into contact with the terminal 85 of the semiconductor package 80, and a lower surface of the first contact portion 111 located below the first hollow 112 is connected to the elastic portion 150. The first hollow 112 is formed by penetrating in the thickness direction (±z direction), and is formed as an empty space with curved left and right sides so that the upper surface of the first contact portion 111 is deformed more easily.

Since the first connection portion 110 is connected to the elastic portion 150, the first connection portion 110 is elastically movable vertically by contact pressure.

When inspecting the semiconductor package 80, the terminal 85 of the semiconductor package 80 is moved downward by making contact with the upper surface of the first connection portion 110. As a result, the elastic portion 150 connected to the first connection portion 110 is compressed and deformed. The first connection portion 110 is moved downward.

The first flange 113 of the first connection portion 110 extends downward from the first contact portion 111 to cover at least a part of a side surface of the elastic portion 150. Here, the first flange 113 extends downward continuously from a width-wise end of the first contact portion 111. The first flange 113 extends from the first contact portion 111 downward (−y direction) so that at least a part of the first flange 113 is provided between the elastic portion 150 and the support portion 130.

The elastic portion 150 is elastically deformed so that the first connection portion 110 and the second connection portion 120 are displaced relative to each other. The connecting portion 140 connects the elastic portion 150 and the support portion 130 to each other. In other words, the connecting portion 140 connects the elastic portion 150 to the support portion 130. The elastic portion 150 includes an upper elastic portion 150a located above the connecting portion 140 and a lower elastic portion 150b located below the connecting portion 140.

When the elastic portion 150 is compressed (more specifically, when the upper elastic portion 150a is compressed), the first flange 113 is lowered downward (−y direction) in a space between the elastic portion 150 and the support portion 130. On the contrary, when the elastic portion 150 is restored, the first flange 113 is raised upward (+y direction) in the space between the elastic portion 150 and the support portion 130.

The support portion 130 faces an inner wall of the guide housing 30 and extends in the length direction (±y direction).

The support portion 130 includes a first support portion 130a located at a first side of the electro-conductive contact pin 100, and a second support portion 130b located at a second side of the electro-conductive contact pin 100. The dimension of the first contact portion 111 in the width direction is smaller than that between the first support portion 130a and the second support portion 130b. The first flange 113 is located within a region between the first support portion 130a and the second support portion 130b.

The first support portion 130a and the second support portion 130b are formed along the length direction of the electro-conductive contact pin 100. The first support portion 130a and the second support portion 130b are integrally connected to the connecting portion 140 formed by extending along the width direction of the electro-conductive contact pin 100. The first connection portion 110 is connected to an upper part of the elastic portion 150, and the second connection portion 120 is connected to a lower part of the elastic portion 150. Since the elastic portion 150 is integrally connected to the first and second support portions 130a and 130b through the connecting portion 140, the electro-conductive contact pin 100 is configured as a single body.

The first flange 113 includes a first left flange 113a located at the first side of the elastic portion 150 and a first right flange 113b located at the second side of the elastic portion 150 opposite to the first left flange 113a. Each of the first left flange 113a and the first right flange 113b is connected to the first contact portion 111.

The first flange 113 of the first connection portion 110 is located to overlap the support portion 130 in the width direction. Specifically, the first flange 113 extends from the first contact portion 111 so that at least a part of the first flange 113 is provided in the space between the support portion 130 and the elastic portion 150. More specifically, at least a part of the first left flange 113a is located between the first support portion 130a and the elastic portion 150, and at least a part of the first right flange 113b is located between the elastic portion 150 and the second support portion 130b.

When the elastic portion 150 is compressed, the first left flange 113a is lowered downward (−y direction) in a space between the elastic portion 150 and the first support portion 130a, and the first right flange 113b is lowered downward (−y direction) in a space between the elastic portion 150 and the second support portion 130b. On the contrary, when elastic portion 150 is restored, the first left flange 113a is raised upward (+y direction) in the space between the elastic portion 150 and the first support portion 130a, and the first right flange 113b is raised upward (+y direction) in the space between the elastic portion 150 and the second support portion 130b.

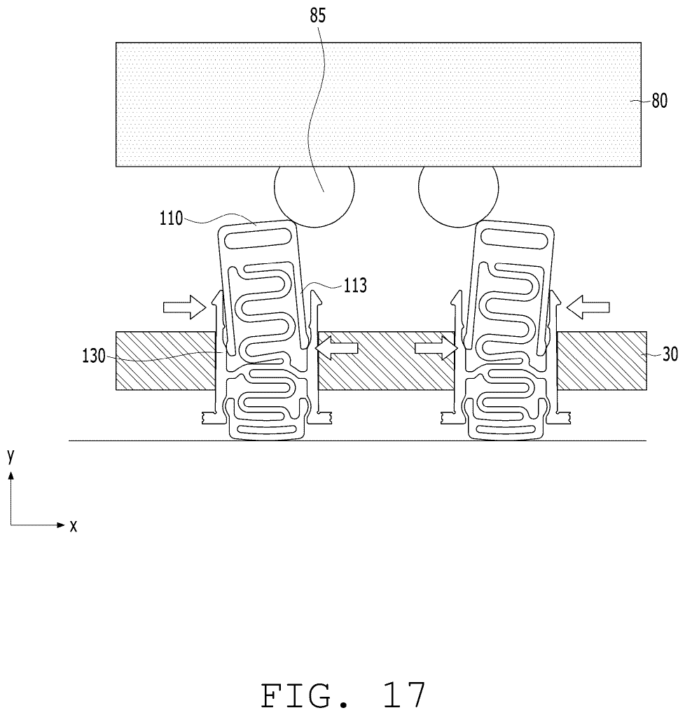

FIG. 17 is a view illustrating a case where the terminal 85 of the semiconductor package 80 is lowered eccentrically rather than in a proper position in the positional relationship with electro-conductive contact pin 100. In accordance with the narrow pitch trend, the size of the terminal 85 becomes smaller. This requires more precise alignment between the terminal 85 and the electro-conductive contact pin 100. However, due to reasons such as assembly and manufacturing tolerances, the terminal 85 of the semiconductor package 80 is more likely to make contact with the electro-conductive contact pin 100 eccentrically rather than in a correct position.

When an eccentric pressure is applied by the terminal 85 in contact with the first connection portion 110 and the first connection portion 110 is thereby tilted to the left, the first left flange 113a is brought into contact with the first support portion 130a and the first right flange 113b is brought into contact with the second support portion 130b. As a result, an upper end of the first support portion 130a supports the first left flange 113a, and the second support portion 130b supports a lower end of the first right flange 113b. With this, the first connection portion 110 can be prevented from being tilted excessively to the left.

In addition, when an eccentric pressure is applied by the terminal 85 in contact with the first connection portion 110 and the first connection portion 110 is thereby tilted to the right, the first left flange 113a is brought into contact with the first support portion 130a and the first right flange 113b is brought into contact with the second support portion 130b. As a result, an upper end of the second support portion 130b supports the second left flange 113b, and the first support portion 130a supports a lower end of the first left flange 113a. With this, the first connection portion 110 can be prevented from being tilted excessively to the right.

When the electro-conductive contact pin 100 is inserted into the guide housing 30, at least a part of an end of the first flange 113 is located inside the through-hole 31. The first flange 113 is in the form of a planar plate. The first flange 113 is configured to be brought into contact with an inner wall of the through-hole 31 when the electro-conductive contact pin 100 receives an eccentric pressure forward and backward. With this structure, the first flange 113 can resist excessive bending deformation occurring forward and backward.

According to the preferred embodiment of the present disclosure, even when an eccentric pressure is applied in the left and right directions, the electro-conductive contact pin 100 can be prevented from being deformed by being excessively tilted in the left and right directions through the configuration of the first flange 113 and the support portion 130. In addition, even when an eccentric pressure is applied in the forward and backward directions, the electro-conductive contact pin 100 can be prevented from being deformed by being excessively tilted in the forward and backward directions through the configuration in which the first flange 113 is brought into contact with the inner wall of the through-hole 31.

A first convex portion 114 protruding toward the support portion 130 is provided at a free end of the first flange 113. A first concave portion 133 is provided in the support portion 130 corresponding to the position of the first convex portion 114. With the configuration of the first convex portion 114 and the first concave portion 133, before the first flange 113 is lowered, the first flange 113 maintains spaced apart from the support portion 130, and when the first flange 113 is lowered, the first flange 113 is gently brought into contact with an inner surface of the support portion 130 and is further lowered while maintaining its contact state. Here, a separation space between the first convex portion 114 and the first concave portion 133 may be formed such that the ratio of the width of the separation space to the height of the separation space is in the range of 1:15 to 1:25. For example, the width of the separation space may be 5 μm and the height of the separation space may be 100 μm. By increasing the aspect ratio of the separation space between the first convex portion 114 and the first concave portion 133, it is possible for the electro-conductive contact pin 100 to have a compact structure in the width direction (±x direction) while increasing the overall thickness H.

When the elastic portion 150 is not compressed, the first flange 113 and the support portion 130 are spaced apart from each other. When the elastic portion 150 is compressed and the first flange 113 is thereby moved downward (−y direction), the first flange 113 is brought into contact with the inner surface of the support portion 130 to form a current path. More specifically, when the first flange 113 is moved downward (−y direction), the first convex portion 114 of the first flange 113 is moved away from the position corresponding to the first concave portion 133 and brought into contact with the inner surface of the support portion 130 to form a current path. Before the elastic portion 150 is compressed, the first flange 113 and the support portion 130 are spaced apart from each other so as not to hinder deformation of the elastic portion 150. As the elastic portion 150 is then compressed, an outer surface of the first flange 113 and the inner surface of the support portion 130 are brought into contact with each other, thereby forming a current path between the support portion 130 and the first flange 113.

The connecting portion 140 includes a first connecting portion 141 connecting the elastic portion 150 and the first support portion 130a, and a second connecting portion 142 connecting the elastic portion 150 and the second support portion 130b. The first connecting portion 141 connects the elastic portion 150 and the first support portion 130a to each other, and the second connecting portion 142 connects the elastic portion 150 and the second support portion 130b to each other.

The first connecting portion 141 and the second connecting portion 142 may be located at the same position or at different positions in the length direction. According to the preferred embodiment of the present disclosure, the first connecting portion 141 and the second connecting portion 142 are provided at the same position in the length direction.

Due to the connecting portion 140, foreign substances introduced from above can be prevented from flowing toward the second connection portion 120, and foreign substances introduced from below can also be prevented from flowing toward the first connection portion 110. By limiting movement of foreign substances introduced inward, the operation of the first and second connection portion 110 and 120 can be prevented from being interfered with by foreign substances.

According to the preferred embodiment of the present disclosure, the electro-conductive contact pin includes a stopper brought into contact with a lower end of the first flange 113 when the first connection portion 110 is moved downward. The first flange is brought into contact with the stopper before the elastic portion 50 reaches its maximum compression state. More specifically, the free end of the first flange 113 may be brought into contact with the connecting portion 140 as the first flange 113 is moved downward. The downward displacement of the first flange 113 causes the lower end of the first flange 113 to be brought into contact with the connecting portion 140, thereby stopping further downward movement of the first contact portion 111. With this, the connecting portion 140 serves as the stopper to limit further downward movement of the first flange 113. Straight portions 153 adjacent in the upper and lower directions do not make contact with each other while the first flange 113 is in contact with the stopper (connecting portion 140). In the above, the connecting portion 140 has been described as a stopper, but any configuration other than the connecting portion 140 may be a stopper that limits downward movement of the first flange 113.

The second connection portion 120 is brought into contact with a connection object (more preferably, a pad 65 of a circuit board 60).

The second connection portion 120 includes a second contact portion 121 brought into contact with the pad 65 of the circuit board 60, and a second flange 123 extending upward from the second contact portion 121 to cover at least a part of the elastic portion 150. When the elastic portion 150 is elastically deformed, the second contact portion 121 and the second flange 123 are moved integrally.

The second contact portion 121 is a portion that is brought into contact with the pad 65 of the circuit board 60.

The second contact portion 121 has a second hollow 122 so that a contact surface of the second contact portion is more easily deformed by the pressure of the semiconductor package 80. A lower surface of the second contact portion 121 located above the second hollow 122 is brought into contact with the pad 65 of the circuit board 60, and an upper surface of the second contact portion 121 located below the second hollow 122 is connected to the elastic portion 150. The second hollow 122 is formed by penetrating in the thickness direction (±z direction), and is formed as an empty space with curved left and right sides so that the upper surface of the second contact portion 121 is deformed more easily.

Since the second connection portion 120 is connected to the elastic portion 150, the second connection portion is elastically movable vertically by contact pressure.

When inspecting the semiconductor package 80, the elastic portion 150 is compressed and deformed as the pad 65 of the circuit board 60 is brought into contact with the lower surface of the second connection portion 120. As the second connection portion 120 is moved upward, the second connection portion 120 is brought into contact with the support portion 130.

The second flange 123 of the second connection portion 120 extends upward from the second contact portion 121 to cover at least a part of the elastic portion 150. The second flange 123 extends from the second contact portion 121 upward (+y direction) so that at least a part of the second flange 123 is provided between the elastic portion 150 and the support portion 130.

When the elastic portion 150 is compressed (more specifically, when the lower elastic portion 150b is compressed), the second flange 123 is raised upward (+y direction) in a space between the elastic portion 150 and the support portion 130. On the contrary, when the elastic portion 150 is restored, the second flange 123 is lowered downward (−y direction) in the space between the elastic portion 150 and the support portion 130.

The second flange 123 includes a second left flange 123a located at the first side of the elastic portion 150 and a second right flange 123b located at the second side of the elastic portion 150 opposite to the second left flange 123a. Each of the second left flange 123a and the second right flange 123b is connected to the second contact portion 121.

The second flange 123 of the second connection portion 120 is located to overlap the support portion 130 in the width direction. Specifically, the second flange 123 extends from the second contact portion 121 so that at least a part of the second flange 123 is provided in the space between the support portion 130 and the elastic portion 150. More specifically, at least a part of the second left flange 123a is located between the first support portion 130a and the elastic portion 150, and at least a part of the second right flange 123b is located between the elastic portion 150 and the second support portion 130b.

When elastic portion 150 is restored, the second left flange 123a is raised upward (+y direction) in the space between the elastic portion 150 and the first support portion 130a, and the second right flange 123b is raised upward (+y direction) in the space between the elastic portion 150 and the second support portion 130b. On the contrary, when elastic portion 150 is restored, the second left flange 123a is lowered downward (−y direction) in the space between the elastic portion 150 and the first support portion 130a, and the second right flange 123b is lowered downward (−y direction) in the space between the elastic portion 150 and the second support portion 130b.

A second convex portion 124 protruding toward the support portion 130 is provided at a free end of the second flange 123. A second concave portion 134 is provided in the support portion 130 corresponding to the position of the second convex portion 124. With the configuration of the second convex portion 124 and the second concave portion 134, before the second flange 123 is raised, the second flange 123 maintains spaced apart from the support portion 130, and when the second flange 123 is raised, the second flange 123 is gently brought into contact with an inner surface of the support portion 130 and is further raised while maintaining its contact state. Here, a separation space between the second convex portion 124 and the second concave portion 134 may be formed such that the ratio of the width of the separation space to the height of the separation space is in the range of 1:15 to 1:25. For example, the width of the separation space may be 5 μm and the height of the separation space may be 100 μm. By increasing the aspect ratio of the separation space between the second convex portion 124 and the second concave portion 134, it is possible for the electro-conductive contact pin 100 to have a compact structure in the width direction (±x direction) while increasing the overall thickness H.

When the elastic portion 150 is not compressed, the second flange 123 and the support portion 130 are spaced apart from each other. When the elastic portion 150 is compressed and the second flange 123 is thereby moved upward (+y direction), the second flange 123 is brought into contact with the inner surface of the support portion 130 to form a current path. More specifically, when the second flange 123 is moved upward (+y direction), the second convex portion 124 of the second flange 123 is brought into contact with the inner surface of the support portion 130 to form a current path. Before the elastic portion 150 is compressed, the second flange 123 and the support portion 130 are spaced apart from each other so as not to hinder deformation of the elastic portion 150. As the elastic portion 150 is then compressed, an outer surface of the second flange 123 and the inner surface of the support portion 130 are brought into contact with each other, thereby forming a current path between the support portion 130 and the second flange 123.

The elastic portion 150 has a uniform cross-sectional

shape in the thickness direction of the electro-conductive contact pin 100. This is possible because the electro-conductive contact pin 100 is manufactured through the plating process.

The elastic portion 150 is connected to at least one of the first connection portion 110 and the second connection portion 120 and is elastically deformable along the length direction (±y direction).

The elastic portion 150 has a shape formed by repeatedly bending a plate having an actual width t in an “S” shape, and the actual width t of the plate is uniform throughout.

The elastic portion 150 is formed by alternately connecting a plurality of straight portions 153 and a plurality of curved portions 154. Each of the straight portions 153 connects the curved portions 154 adjacent in the left and right directions, and each of the curved portions 154 connects the straight portions 153 adjacent in the upper and lower directions. The curved portions 154 have an arc shape.

The straight portions 153 are disposed at a central portion of the elastic portion 150, and the curved portions 154 are disposed at outer peripheral portions of the elastic portion 150. The straight portions 153 are provided parallel to the width direction so that the curved portions 154 are more easily deformed by contact pressure.

In order to prevent the electro-conductive contact pin 100 installed in the inspection device 11 from being separated from the guide housing 30, a first locking portion 131 is provided at a first end of the support portion 130 and a second locking portion 132 is provided at a second end of the support portion.

The first locking portion 131 and the second locking portion 132 are formed to protrude outward in the width direction. With this, the electro-conductive contact pin 100 may be prevented from being separated from the guide housing 30 after being inserted into the guide housing 30.

The first locking portion 131 prevents the electro-conductive contact pin 100 from being separated downward from the guide housing 30, and the second locking portion 132 prevents the electro-conductive contact pin 100 from being separated upward from the guide housing 30.

Hereinafter, a method of manufacturing the electro-conductive contact pin 100 according to the preferred embodiment of the present disclosure will be described.

FIG. 6A is a plan view illustrating the mold 1000 in which the inner space 1100 is formed. FIG. 6B is a sectional view taken along line A-A′ of FIG. 6A.

The mold 1000 may be made of an anodic aluminum oxide film, a photoresist, a silicon wafer, or a material similar thereto. However, a preferred material for the mold 1000 is the anodic aluminum oxide film. The anodic aluminum oxide film refers to a film formed by anodization of a metal as a base material, and pores refer to holes formed in the process of forming the anodic aluminum oxide film by the anodization of the metal. For example, when the metal as the base material is aluminum (Al) or an aluminum alloy, the anodization of the base material forms an anodic aluminum oxide film consisting of anodized aluminum (Al₂O₃) on a surface of the base material. However, the metal as the base material is not limited thereto, and includes Ta, Nb, Ti, Zr, Hf, Zn, W, Sb, or an alloy of these metals. The resulting anodic aluminum oxide film includes a barrier layer in which no pores are formed therein vertically, and a porous layer in which pores are formed therein. After removing the base material on which the anodic aluminum oxide film including the barrier layer and the porous layer is formed, only the anodic aluminum oxide film consisting of anodized aluminum (Al₂O₃) remains. The anodic aluminum oxide film may have a structure in which the barrier layer formed during the anodization is removed to expose the top and bottom of the pores, or a structure in which the barrier layer formed during the anodization remains to close one of the top and bottom of the pores.

The anodic aluminum oxide film has a coefficient of thermal expansion of 2 to 3 ppm/° C. With this range, the anodic aluminum oxide film only undergoes a small amount of thermal deformation due to temperature when exposed to a high-temperature environment. Therefore, even when the electro-conductive contact pin 100 is manufactured in a high-temperature environment, a precise electro-conductive contact pin 100 can be manufactured without thermal deformation.

Since the electro-conductive contact pin 100 according to the preferred embodiment is manufactured using the mold 1000 made of the anodic aluminum oxide film instead of a photoresist mold, there is an effect of realizing shape precision and a fine shape, which were limited in realization with the photoresist mold. In addition, when the conventional photoresist mold is used, an electro-conductive contact pin with a thickness of 40 μm can be manufactured, but when the mold 1000 made of the anodic aluminum oxide film is used, an electro-conductive contact pin 100 with a thickness in the range of 100 μm to 200 μm can be manufactured.

A seed layer 1200 is provided on a lower surface of the mold 1000. The seed layer 1200 may be provided on the lower surface of the mold 1000 before the inner space 1100 is formed in the mold 1000. Meanwhile, a support substrate (not illustrated) is formed under the mold 1000 to improve handling of the mold 1000. In this case, the seed layer 1200 may be formed on an upper surface of the support substrate, and then the mold 1000 having the inner space 1100 may be coupled to the support substrate. The seed layer 1200 may be made of copper (Cu), and may be formed by a deposition method.

The inner space 1100 may be formed by wet-etching the mold 1000 made of the anodic aluminum oxide film. To this end, a photoresist may be provided on the upper surface of the mold 1000 and patterned, and then the anodic aluminum oxide film in a patterned and open area may react with an etchant to form the inner space 1100.

Thereafter, an electroplating process is performed on the inner space 1100 of the mold 1000 to form an electro-conductive contact pin 100. FIG. 6C is a plan view illustrating the electroplating process performed on the inner space 1100. FIG. 6D is a sectional view taken along line A-A′ of FIG. 6C.

During the electroplating process, a metal layer is formed while growing in the thickness direction (±z direction) of the mold 1000. Therefore, the metal layer thus formed has a uniform cross-sectional shape in the thickness direction (±z direction) of the electro-conductive contact pin 100. A plurality of metal layers are stacked in the thickness direction (±z direction) of the electro-conductive contact pin 100. The plurality of metal layers include a first metal layer 101 and a second metal layer 102. The first metal layer 101 is a metal having relatively high wear resistance compared to the second metal layer 102, and may be selected from the group consisting of rhodium (Rh), platinum (Pt), iridium (Ir), palladium, and an alloy of these metals; the group consisting of a palladium-cobalt (PdCo) alloy and a palladium-nickel (PdNi) alloy; or the group consisting of a nickel-phosphor (NiPh) alloy, a nickel-manganese (NiMn) alloy, a nickel-cobalt (NiCo) alloy, and a nickel-tungsten (NiW) alloy. The second metal layer 102 is a metal having relatively high electrical conductivity compared to the first metal layer 101, and may be selected from the group consisting of copper (Cu), silver (Ag), gold (Au), and an alloy of these metals.

The first metal layer 101 is provided on each of a lower surface and an upper surface of the electro-conductive contact pin 100 in the thickness direction (±z direction), and the second metal layer 102 is provided between the respective first metal layers 101. For example, the electro-conductive contact pin 100 may be provided by sequentially stacking the first metal layer 101, the second metal layer 102, and the first metal layer 101, and the number of stacked layers may be at least three.

Meanwhile, after the plating process is completed, the temperature is raised to a high temperature and pressure is applied to pressurize the metal layers on which the plating process is completed so that the first metal layer 101 and the second metal layer 102 are made denser. When a photoresist is used as a mold, the process of raising the temperature to a high temperature and applying pressure cannot be performed because the photoresist exists around the metal layers after the plating process is completed. On the contrary, according to the preferred embodiment of the present disclosure, since the mold 1000 made of the anodic aluminum oxide film is provided around the metal layers on which the plating process is completed, even when the temperature is raised to a high temperature, it is possible to densify the first metal layer 101 and the second metal layer 102 with minimized deformation because of the low coefficient of thermal expansion of the anodic aluminum oxide film. Therefore, it is possible to obtain the first metal layer 101 and the second metal layer 102 with a higher density compared to the technique using the photoresist as a mold.

When the electroplating process is completed, the mold 1000 and the seed layer 1200 are removed. When the mold 1000 is made of the anodic aluminum oxide film, the mold 1000 is removed using a solution that selectively reacts with the anodic aluminum oxide film. In addition, when the seed layer 1200 is made of copper (Cu), the seed layer 1200 is removed using a solution that selectively reacts with copper (Cu).

Referring to FIG. 7, the electro-conductive contact pins 100 according to the preferred embodiment includes a plurality of fine trenches 88 provided on a side surface thereof. The fine trenches 88 are formed to extend in the thickness direction (±z direction) of the electro-conductive contact pin 100 on the side surface of the electro-conductive contact pin 100. Here, the thickness direction (±z direction) of the electro-conductive contact pin 100 refers to a direction in which a metal filling material grows during electroplating.

The fine trenches 88 have a depth in the range of 20 nm to 1 μm and a width in the range of 20 nm to 1 μm. Here, because the fine trenches 88 are resulted from the formation of the pores formed during the manufacture of the mold 1000 made of the anodic aluminum oxide film, the width and depth of the fine trenches 88 are equal to or less than the diameter of the pores formed in the mold 1000 made of the anodic aluminum oxide film. Meanwhile, in the process of forming the inner space 1100 in the mold 1000 made of the anodic aluminum oxide film, portions of the pores of the mold 1000 made of the anodic aluminum oxide film may be crushed by an etchant to at least partially form a fine trench 88 having a depth larger than the diameter of the pores formed during the anodization.

Since the mold 1000 made of the anodic aluminum oxide film includes a large number of pores, at least a part of the mold 1000 made of the anodic aluminum oxide film is etched to form the inner space 1100, and the metal filling material is formed in the inner space by 1100 electroplating, the fine trenches 88 are formed on the side surface of the electro-conductive contact pin 100 as a result of contact between the contact pin and the pores of the mold 1000 made of the anodic aluminum oxide film.

The fine trenches 88 as described above can contribute to increasing the surface area of the side surface of the electro-conductive contact pin 100. In addition, with the configuration of the fine trenches 88 formed on the side surface of the electro-conductive contact pin 100, heat generated in the electro-conductive contact pin 100 can be rapidly dissipated, thereby suppressing a rise in the temperature of the electro-conductive contact pin 100. In addition, with the configuration of the fine trenches 88 formed on the side surface of the electro-conductive contact pin 100, the torsional resistance ability of the electro-conductive contact pin 100 against deformation can be improved.

In order to effectively cope with the test of high-frequency characteristics of the semiconductor package 80, the overall length L of the electro-conductive contact pin 100 has to be short. Therefore, the length of the elastic portion 150 has to also be shortened. However, when the length of the elastic portion 150 is shortened, a problem occurs in that contact pressure increases. In order to shorten the length of the elastic portion 150 without increasing the contact pressure, the actual width t of the plate constituting the elastic portion 150 has to be small. However, when the actual width t of the plate constituting the elastic portion 150 is shortened, a problem occurs in that the elastic portion 150 tends to be damaged. In order to shorten the length of the elastic portion 150 without increasing the contact pressure and prevent damage to the elastic portion 150, the overall thickness H of the plate constituting the elastic portion 130 has to be large.

The electro-conductive contact pin 100 according to the preferred embodiment is formed such that the actual width t of the plate is small while the overall thickness H of the plate is large. In other words, the overall thickness H of the plate is configured to be large compared to the actual width t thereof. Preferably, the actual width t of the plate constituting the electro-conductive contact pin 100 is in the range of 5 μm to 15 μm, the overall thickness H thereof is in the range of 70 μm to 200 μm, and the actual width t and the overall thickness H of the plate have a ratio in the range of 1:5 to 1:30. For example, the actual width t of the plate may be substantially 10 μm, and the overall thickness H thereof may be 100 μm, so that the actual width t and the overall thickness H of the plate may have a ratio of 1:10. This is possible because the mold 1000 made of the anodic aluminum oxide film is used.

With this, it is possible to shorten the length of the elastic portion 150 while preventing damage to the elastic portion 150, and it is possible for the elastic portion 150 to have an appropriate contact pressure even when the length thereof is shortened. Furthermore, as it is possible to increase the overall thickness H of the plate constituting the elastic portion 150 compared to the actual width t thereof, the resistance to moments acting in the front and rear directions of the elastic portion 150 is increased, resulting in improved contact stability.

In addition, since the electro-conductive contact pin 100 is manufactured using the mold 1000 made of the anodic aluminum oxide film, it is possible to set the distance between the first flange 113 and the support portion 130 to 5 μm. In the case of using the photoresist as a mold, it is difficult to implement a separation distance having a high aspect ratio, but by using the mold 1000 made of the anodic aluminum oxide film, it is possible to implement a separation distance having a high aspect ratio.

The overall thickness H and the overall width W of the electro-conductive contact pin 100 have a ratio in the range of 1:1 to 1:5. Preferably, the overall thickness H of the electro-conductive contact pin 100 is in the range of 70 μm to 200 μm, and the overall width W of the electro-conductive contact pin 100a is in the range of 100 μm to 500 μm. More preferably, the overall width W of the electro-conductive contact pin 100 is in the range of 150 μm to 400 μm. By shortening the overall width W of the electro-conductive contact pin 100 as described above, it is possible to implement a narrower pitch.

Meanwhile, the overall thickness H and the overall width W of the electro-conductive contact pin 100 may be configured to be substantially the same. Therefore, it is not necessary to join a plurality of separately manufactured electro-conductive contact pins 100 in the thickness direction so that the overall thickness H and the overall width W become substantially the same. In addition, as it is possible to make the overall thickness H and the overall width W of the electro-conductive contact pin 100 substantially the same, the resistance to moments acting in the front and rear directions of the electro-conductive contact pin 100 is increased, resulting in improved contact stability. Furthermore, with the configuration in which the overall thickness H of the electro-conductive contact pin 100 is equal to or larger than 70 μm and the ratio of the overall thickness H to the overall width W thereof is in the range of 1:1 to 1:5, overall durability and deformation stability of the electro-conductive contact pin 100 can be improved and thereby contact stability with the terminal 85 can be improved. In addition, as the overall thickness H of the electro-conductive contact pin 100 is configured to be equal to or larger than 70 μm, current carrying capacity can be improved.

A conventional electro-conductive contact pin manufactured using a photoresist mold cannot have a large overall thickness due to alignment problems because the mold is formed by stacking a plurality of photoresists. As a result, the conventional electro-conductive contact pin has a smaller overall thickness H compared to an overall width W. For example, in the case of the conventional electro-conductive contact pin, the overall thickness H may be less than 70 μm and the overall thickness H and the overall width W may have a ratio in the range of 1:2 to 1:10. Therefore, the resistance to moments that deform the electro-conductive contact pin 100 in the front and rear directions by contact pressure is weak. Conventionally, in order to prevent problems occurring due to excessive deformation of the elastic portion on front and rear surfaces of the electro-conductive contact pin 100, it should be considered to additionally form a housing on the front and rear surfaces of the electro-conductive contact pin 100. However, according to the preferred embodiment of the present disclosure, an additional housing is not necessary.

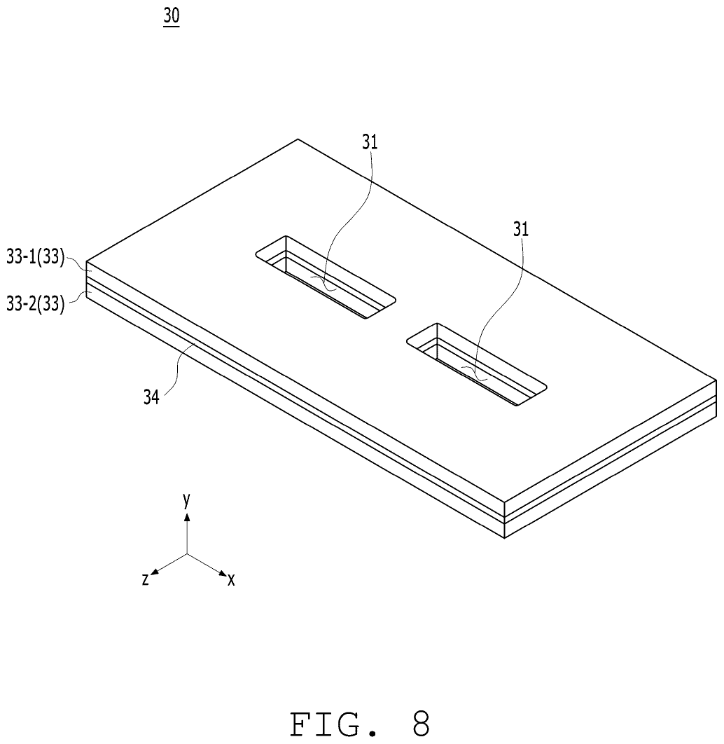

Hereinafter, the guide housing 30 will be described with reference to FIG. 8.

The guide housing 30 has the through-hole 31 into which the electro-conductive contact pin 100 is inserted.

The guide housing 30 includes a polyimide (PI) film 33.

The first locking portion 131 of the electro-conductive contact pin 100 located above first surface of the guide housing 30 is supported by the polyimide film 33, and the second locking portion 132 of the electro-conductive contact pin 100 located below a second surface of the guide housing 30 is supported by the polyimide film 33.

Here, a case where the first locking portion 131 of the electro-conductive contact pin 100 is supported by the polyimide film 33 may be after the electro-conductive contact pin 100 is inserted into the guide housing 30 from an upper side of the guide housing, or when the electro-conductive contact pin 100 is entirely moved downward due to stroke displacement of the semiconductor package 80. In addition, a case where the second locking portion 132 of the electro-conductive contact pin 100 is supported by the polyimide film 33 may be when the electro-conductive contact pin 100 is entirely moved upward by the pressure of the circuit board 60 after the electro-conductive contact pin 100 is inserted into the guide housing 30.

A pressing force acting between the semiconductor package 80 and the circuit board 60 causes the electro-conductive contact pin 100 to pressurize the first surface or the second surface of the guide housing 30. At this time, since the first surface and/or the second surface of the guide housing 30 are made of the polyimide film 33, the electro-conductive contact pin 100 and/or the guide housing 30 can be prevented from being damaged.

In addition, the guide housing 30 is fixed while a plurality of electro-conductive contact pins 100 are inserted and installed into a plurality of through-holes 31 of the guide housing 30, respectively. When manually fixing and installing the guide housing 30, even when the guide housing 30 is handled roughly, the guide housing 30 can be prevented from being easily damaged because the guide housing 30 includes the polyimide film 33.

In addition, since the guide housing 30 adopts the polyimide film 33, the guide housing 30 has flexibility against bending. The inspection device 11 has processing tolerances, assembly tolerances, etc. Due to these tolerances, stroke may be excessively applied to a part of the semiconductor package 80. In this case, the guide housing 30 including the polyimide film 33 is elastically bent and deformed against excessive overstroke, thereby preventing the electro-conductive contact pin 100 and/or the guide housing 30 from being damaged.

However, when the guide housing 30 is composed of only the polyimide film 33, there is a risk that the guide housing 30 may easily be deformed or broken beyond its elastic range limit when subjected to bending deformation. For this reason, the guide housing 30 includes a plurality of polyimide films 33. In addition, a reinforcing layer 34 is provided between adjacent polyimide films 33 that are stacked on top of each other.

The reinforcing layer 34 has a flexural modulus greater than that of the polyimide film 33 and is integrally bonded to the adjacent polyimide films 33. With this, the reinforcing layer 34 improves the mechanical rigidity of the polyimide films 33. The reinforcing layer 34 may be made of a thermosetting plastic. The reinforcing layer 34 may be made of an epoxy-based thermosetting plastic.

The guide housing 30 may be formed by stacking the plurality of polyimide films 33. The guide housing 30 includes a first polyimide film 33-1 and a second polyimide film 33-2. The guide housing 30 is formed by stacking the first polyimide film 33-1 and the second polyimide film 33-2 with the reinforcing layer 34 interposed therebetween. The through-hole 31 is formed by sequentially penetrating the first polyimide film 33-1, the second polyimide film 33-2, and the reinforcing layer 34. Here, the number of stacked polyimide films 33 is not limited to two, but may be two or more.

Since the first polyimide film 33-1 and the second polyimide film 33-2 are formed in a vertically symmetrical structure with respect to the reinforcing layer 34, the guide housing 30 can be easily restored after being bent and deformed. In addition, since upper and lower parts of the guide housing 30 have the same thermal expansion rate in a high-temperature environment, the guide housing can be prevented from being bent in any one direction.

The thickness of the first polyimide film 33-1 and the thickness of the second polyimide film 33-2 may be the same and may be in the range of 50 μm to 200 μm, and the thickness of the reinforcing layer 34 may be smaller than those of the first polyimide film 33-1 and the second polyimide film 33-2 and may be in the range of 20 μm to 70 μm. The overall thickness of the guide housing 30 may be in the range of 70 μm to 270 μm.

The pressing force acting between the semiconductor package 80 and the circuit board 60 acts in the length direction (±y direction) of the electro-conductive contact pin 100, and the elastic portion 150 of the electro-conductive contact pin 100 is compressed and deformed in the length direction (±y direction) to buffer the pressing force acting between the semiconductor package 80 and the circuit board 60. Therefore, since the pressure applied to the electro-conductive contact pin 100 in the horizontal direction with respect to the guide housing 30 is not large, the guide housing 30 only needs to be thick enough to support the pressure that the electro-conductive contact pin 100 applies to the guide housing 30 when relatively displaced in the length direction (±y direction) with respect to the Since the guide housing 30 including the guide housing. polyimide film 33 is formed with a sufficient thickness and most of the pressing force acting between the semiconductor package 80 and the circuit board 60 is transmitted to the electro-conductive contact pin 100, it is possible to use the polyimide film 33 for the purpose of supporting the electro-conductive contact pin 100. When the electro-conductive contact pin 100 is relatively displaced in the length direction (±y direction) with respect to the guide housing 30, the polyimide film 33 of the guide housing 30 buffers the pressure that the electro-conductive contact pin 100 applies to the guide housing 30, thereby preventing damage to the electro-conductive contact pin 100 and/or the guide housing 30.

Meanwhile, an insert film 90 that determines the position of the semiconductor package 80 may be provided by including a polyimide film, and the guide housing 30 that determines the position of the electro-conductive contact pin 100 may also be provided by including the polyimide film 33. With this, even when the insert film 90 and the guide housing 30 are thermally deformed, positional misalignment between the electro-conductive contact pin 100 and the semiconductor package 80 can be minimized.

In a state where the first polyimide film 33-1, the reinforcing layer 34, and the second polyimide film 33-2 are sequentially stacked and integrated, they are drilled using a laser to form the through-hole 31. A plurality of through-holes 31 are formed in the guide housing 30.

The overall dimension W of the electro-conductive contact pin 100 in the width direction (±x direction) is formed to be larger than the overall thickness H in the thickness direction (±z direction), so that the outer shape of the electro-conductive contact pin 100 is preferably rectangular. With this, the electro-conductive contact pin 100 can be prevented from being incorrectly inserted while it is rotated 90 degrees.

In addition, with the configuration of the first locking portion 131 and the second locking portion 132, the overall width W of the electro-conductive contact pin 100 in the width direction (±x direction) is longer than the length of sides of the through-hole 31 facing in a first direction of the through-hole, and the overall thickness H of the electro-conductive contact pin 100 in the thickness direction (±z direction) is smaller than the length of sides of the through-hole 31 facing in a second direction of the through-hole. Here, the first direction of the through-hole 31 refers to the width direction (±x direction) of the electro-conductive contact pin 100, and the second direction of the through-hole 31 refers to the thickness direction (±z direction) of the electro-conductive contact pin 100.

The electro-conductive contact pin 100 is supported by the first locking portion 131 on two sides of the through-hole 31 facing in the first direction, but is not supported on two sides of the through-hole 31 facing in the second direction. Therefore, the electro-conductive contact pin 100 is allowed to be moved in the direction of two sides of the through-hole 31 facing in the second direction, so that fine adjustment of alignment of the electro-conductive contact pin 100 is possible in the range of several to several tens of μm.

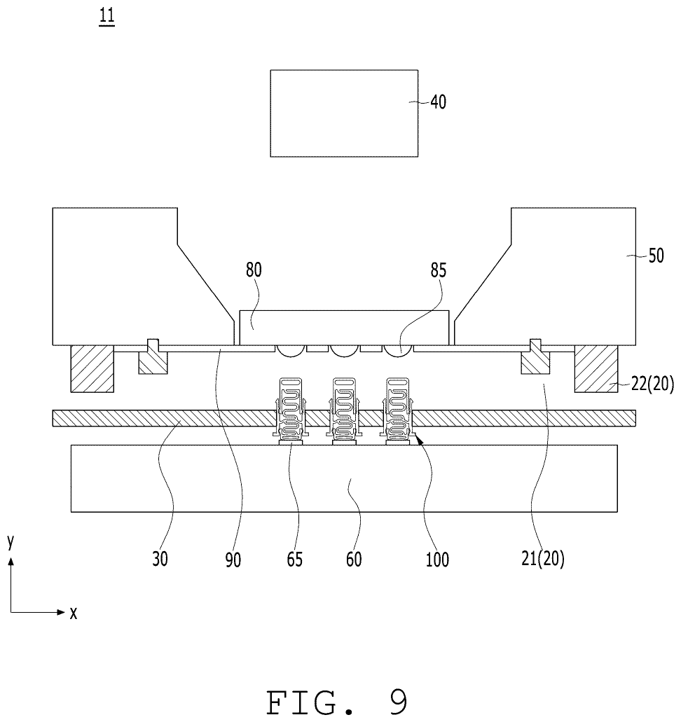

Referring to FIG. 9, the inspection device 11 includes an insert 50 having a receiving portion in which the semiconductor package 80 is received, the guide housing 30 in which the electro-conductive contact pin 100 is inserted and installed, and a pusher 40 for pressurizing the semiconductor package 80.

A plurality of electro-conductive contact pins 100 are installed in the guide housing 30. The insert 50 receives the semiconductor package 80 so that testing is performed on the semiconductor package 80 in a stable state. The insert film 90 having holes provided to guide terminals 85 of the semiconductor package 80 is installed at a lower part of the insert 50. The insert film 90 is provided between the semiconductor package 80 and the electro-conductive contact pins 100. When inspecting the semiconductor package 80, the insert film 90 accurately guides a contact position of the terminals 85 of the semiconductor package 80 by allowing the terminals of the semiconductor package to be inserted into the holes provided in the insert film 90. The pusher 40 serves to pressurize the semiconductor package 80 seated in the receiving portion of the insert 50 at a constant pressure. The semiconductor package 80 pressurized by the pusher 40 may be electrically connected to pads 65 of the circuit board 60 through the electro-conductive contact pins 100 installed in the guide housing 30.

At the lower part of the insert 50, a fixing pin 21 for fixing the insert film 90 to the insert 50 and an alignment key 22 for precisely adjusting the position of the insert film 90 are provided. The fixing pin 21 and the alignment key 22 are interference members 20 and are provided to protrude downward from the lower part of the A structure that supports the semiconductor insert 50. package 80 without the insert film 90 is also possible. In this case, an interference member 20 may be a support protrusion (not illustrated) that supports the edge of the semiconductor package 80 at the lower part of the insert 50. The interference member 20 is provided to protrude further downward than the terminals of the semiconductor package 80 while the semiconductor package 80 is received in the receiving portion of the insert 50.

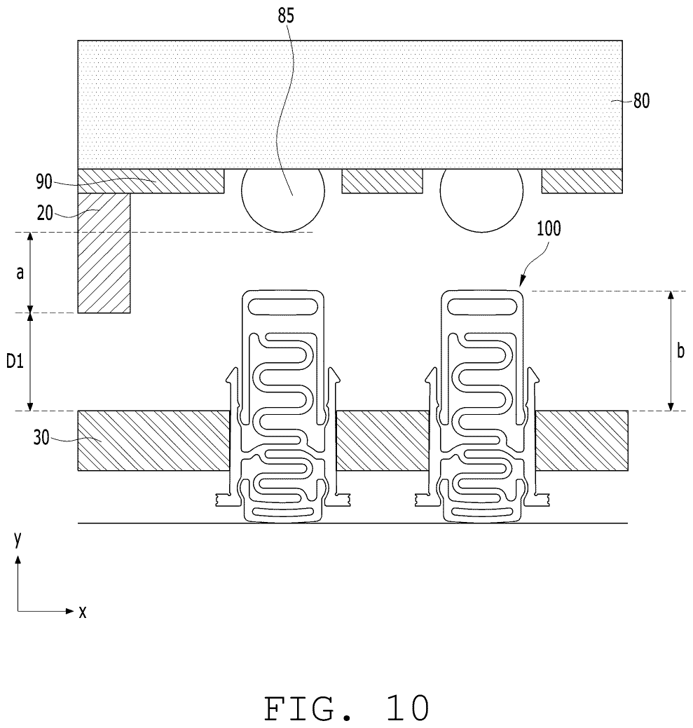

With reference to FIGS. 10 to 13, a detailed description will be given of a configuration that prevents the guide housing 30 and/or the electro-conductive contact pins 100 from being damaged by the interference member 20 protruding downward from the terminals 85, while adopting the guide housing 30 formed with a uniform overall thickness including a part corresponding to the position of the interference member 20.

The process of the inspection device 11 may be divided into a pre-pusher pressurization step, a contact step, and a stroke completion step according to a downward stroke of the semiconductor package 80 caused by pressurization of the pusher 40. The inspection device 11 inspects the semiconductor package 80 by sequentially subjecting the inspection device to the pre-pusher pressurization step, the contact step, and the stroke completion step. The pre-pusher pressurization step is a state where the semiconductor package 80 is seated on the insert 50 and is a step before the pusher 40 pressurizes the semiconductor package 80 toward the electro-conductive contact pins 100. The contact step is a state where the semiconductor package 80 seated on the insert 50 is pressurized by the pusher 40 after the pre-pusher pressurization step and the terminals 85 of the semiconductor package 80 begin to make contact with the electro-conductive contact pins 100. The stroke completion step is a state where the semiconductor package 80 is lowered to a preset stroke limit value by continuous pressurization of the pusher 40 after the contact step.

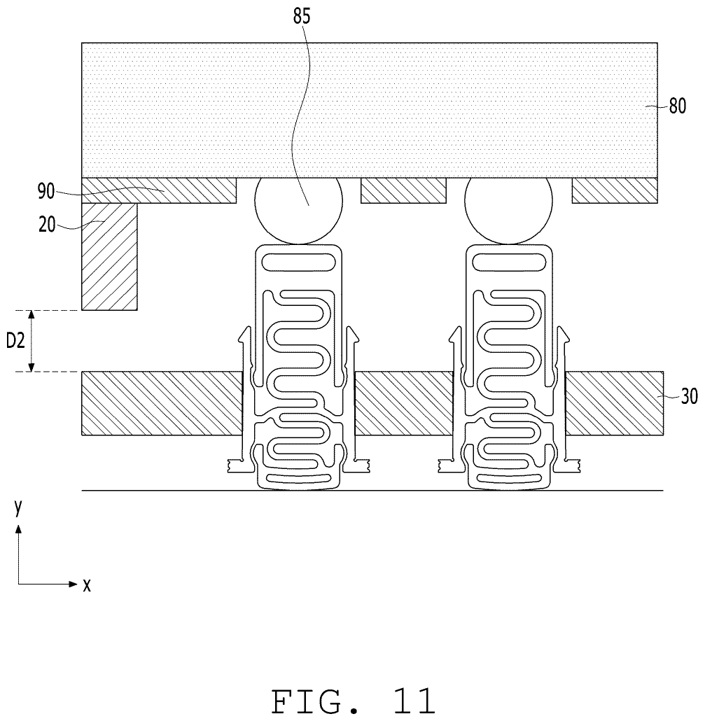

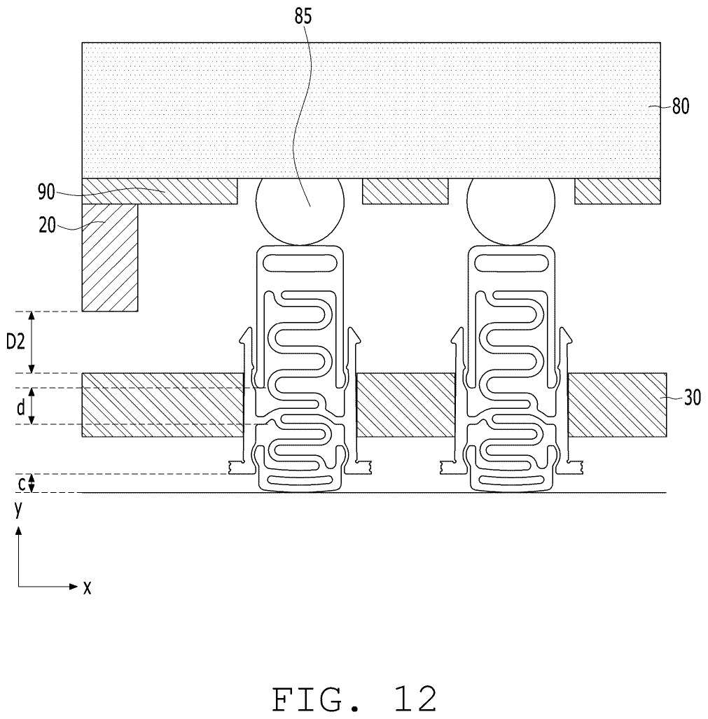

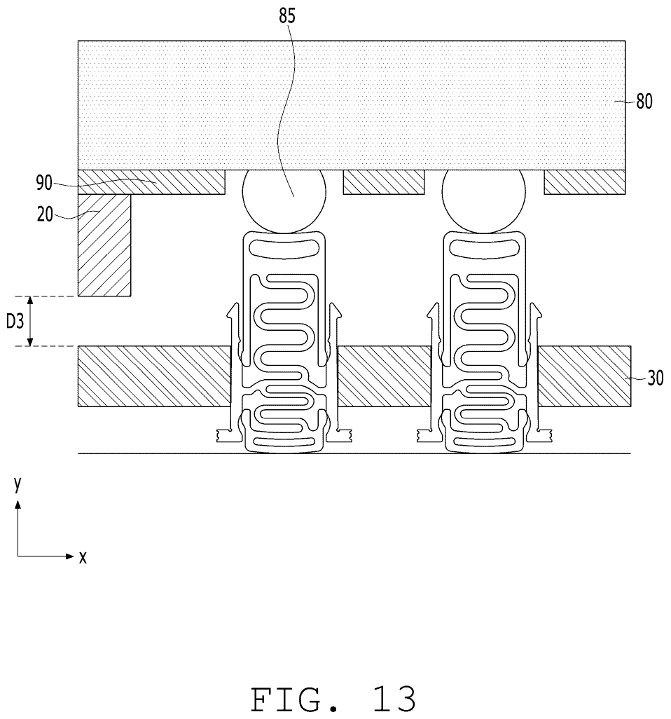

FIG. 10 is a view illustrating the pre-pusher pressurization step, FIGS. 11 and 12 are views illustrating the contact step, and FIG. 13 is a view illustrating the stroke completion step.

First, the pre-pusher pressurization step will be described with reference to FIG. 10.

The semiconductor package 80 is seated on the insert film 90. The electro-conductive contact pin 100 is installed in the guide housing 30. The second connection portion 120 of the electro-conductive contact pin 100 is in contact with the pad 65 of the circuit board 60.

The protrusion length of the first connection portion 110 protruding from an upper surface of the guide housing 30 is longer than that of the second connection portion 120 protruding from a lower surface of the guide housing 30. The first connection portion 110 and the second connection portion 120 are displaceable in the vertical direction. The displacement range of the first connection portion 110 is longer than that of the second connection portion 120. In addition, at least one of the first connection portion 110 and the second connection portion 120 is brought into contact with the support portion 130 during displacement to form a current path.

The electro-conductive contact pin 100 has a protrusion length b that protrudes upward from the upper surface of the guide housing 30. The interference member 20 has a protrusion length a that protrudes downward from a lower end of the terminal 85. The protrusion length b of the electro-conductive contact pin 100 protruding upward from the upper surface of the guide housing 30 is formed to be longer than the protrusion length a of the interference member 20 protruding downward from the lower end of the terminal 85.

In the pre-pusher pressurization step, a lower end of the interference member 20 does not make contact with the guide housing 30. In the pre-pusher pressurization step, the distance from the lower end of the interference member 20 to the upper surface of the guide housing 30 is referred to as a first separation distance D1. The lower end of the interference member 20 is located apart from the upper surface of the guide housing 30 by the first separation distance D1. In the pre-pusher pressurization step, the terminal 85 of the semiconductor package 80 does not make contact with the electro-conductive contact pin 100, and the first separation distance D1 is formed. The first separation distance D1 may be in the range of 5 μm to 200 μm.

In order to prevent the guide housing 30 and/or the electro-conductive contact pin 100 from being damaged by the interference member 20 protruding downward from the terminal 85 while forming the guide housing 30 to have a uniform overall thickness, in the preferred embodiment of the present disclosure, the terminal 85 of the semiconductor package 80 does not make contact with the electro-conductive contact pin 100 in the pre-pusher pressurization step, and the protrusion length b of the electro-conductive contact pin 100 protruding upward from the upper surface of the guide housing 30 is formed to be longer than the protrusion length a of the interference member 20 protruding downward from the lower end of the terminal 85.

For example, the overall length L of the semiconductor package 80 may be 400 μm, the thickness of the guide housing 30 may be 150 μm, the protrusion length b may be 200 μm, the protrusion length a may be 110 μm, and the first separation distance D1 may be 140 μm. However, these dimensions may vary depending on the specifications of the inspection device 11.

Next, the contact step will be described with reference to FIGS. 11 and 12.

Referring to FIG. 11, when the semiconductor package 80 is pressurized by the pusher 40, the semiconductor package 80 is lowered toward the electro-conductive contact pin 100. After the semiconductor package 80 is lowered by a predetermined distance, the terminal 85 of the semiconductor package is brought into contact with the first connection portion 110 of the electro-conductive contact pin 100. Here, the downward stroke of the semiconductor package 80 may be 50 μm.

In the contact step, the lower end of the interference member 20 does not make contact with the guide housing 30. In the contact step, the distance from the lower end of the interference member 20 to the upper surface of the guide housing 30 is referred to as a second separation distance D2. In other words, in the contact step where the semiconductor package 80 is pressurized toward the electro-conductive contact pin 100 so that the terminal 85 of the semiconductor package 80 is brought into contact with the electro-conductive contact pin 100, the second separation distance D2 is formed so that the interference member 20 does not make contact with the guide housing 30. The lower end of the interference member 20 is located apart from the upper surface of the guide housing 30 by the second Here, the second separation separation distance D2. distance D2 may be 90 μm.

Referring to FIG. 12, in the contact step, the first connection portion 110 of the electro-conductive contact pin 100 is in a state where it is allowed to be further lowered by a separation distance d between the first flange 113 and the connecting portion 140, and the second connection portion 120 is in a state where it is allowed to be further raised by a distance c between the second locking portion 132 and the circuit board 60 or the pad 65. In addition, the first contact portion 111 of the first connection portion 110 is in a state where it is allowed to be bent and deformed by the first hollow 112. Here, the separation distance c may be 30 μm and the separation distance d may be 47 μm. In addition, the distance by which the terminal 85 is allowed to be further lowered due to bending deformation of the first contact portion 111 may be 3 μm. However, these dimensions may vary depending on the specifications of the inspection device 11.

Next, the stroke completion step will be described with reference to FIG. 13.

The semiconductor package 80 is lowered by a preset stroke limit value. In the stroke completion step, the total downward stroke of the semiconductor package 80 may be 100 μm. That is, the stroke limit value may be 100 μm.

When the semiconductor package 80 is further lowered after the contact step, the first connection portion 110 is lowered and the second connection portion 120 is raised. As a result, in the stroke completion step, the first connection portion 110 (more specifically, the first flange 113) is brought into contact with a part of an inner wall of the support portion 130 to form a current path, and the second connection portion 120 (more specifically, the second flange 123 of the electro-conductive contact pin 100 is brought into contact with a part of the inner wall of the support portion 130 to form a current path. In addition, the first contact portion 111 of the first connection portion 110 is bent and deformed by the first hollow 112.

In the stroke completion step, the lower end of the interference member 20 does not make contact with the guide housing 30. In the stroke completion step, the distance from the lower end of the interference member 20 to the upper surface of the guide housing 30 is referred to as a third separation distance D3. In other words, in the stroke completion step where the terminal 85 of the semiconductor package 80 is further lowered to the stroke limit value after contact with the electro-conductive contact pin 100, the third separation distance D3 is formed so that the interference member 20 does not make contact with the guide housing 30. The lower end of the interference member 20 is located apart from the upper surface of the guide housing 30 by the third separation distance D3. Here, the third separation distance D3 may be 40 μm. The difference between the first separation distance D1 and the third separation distance D3 corresponds to the set stroke limit value.

When defining the pre-pusher pressurization step, the contact step, and the stroke completion step on the basis of the downward stroke of the semiconductor package 80, the pre-pusher pressurization step is when the downward stroke of the semiconductor package 80 is zero (0), the contact step is when the downward stroke of the semiconductor package 80 is 50 μm, and the stroke completion step is when the downward stroke of the semiconductor package 80 is the stroke limit value (100 μm). Even when the semiconductor package 80 is lowered to the stroke limit value, the interference member 20 does not make contact with the upper surface of the guide housing 30.

Meanwhile, when the downward stroke of the semiconductor package 80 is between the contact step and the stroke completion step, the interference member 20 may be brought into contact with the upper surface of the guide housing 30 depending on the length dimension. However, since the semiconductor package 80 is in a state where it is allowed to be further compressed until a maximum compression step, even when the interference member 20 is brought into contact with the upper surface of the guide housing 30 and pressurizes the guide housing 30, the electro-conductive contact pin 100 can be prevented from being damaged.

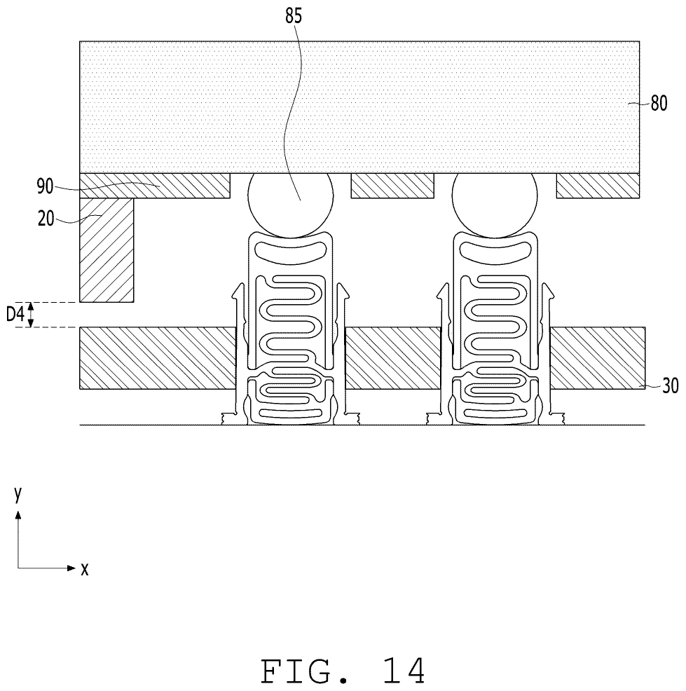

FIG. 14 is a view illustrating a maximum compression step in which the electro-conductive contact pin 100 is compressed to the maximum possible extent. As illustrated in FIG. 14, the first connection portion 110 is further lowered until the first flange 113 is brought into contact with the connecting portion 140, and the second connection portion 120 is further raised until the circuit board 60 or the pad 65 is brought into contact with the second locking portion 132.

Although the semiconductor package 80 needs to be lowered only to the preset stroke limit value, the terminal 85 of the semiconductor package 80 may be further lowered beyond the stroke limit value due to reasons such as the manufacturing tolerance of the terminal 85, the assembly tolerance of the inspection device 11, and the manufacturing tolerance of the inspection device 11. In the stroke completion step where the terminal 85 of the semiconductor package 80 is further lowered to the stroke limit value after contact with the electro-conductive contact pin 100, the electro-conductive contact pin 100 is allowed to be further compressed even when the interference member 20 is brought into contact with the guide housing 30. Therefore, even when the semiconductor package 80 is lowered beyond the stroke limit value, the guide housing 30 and/or the electro-conductive contact pin 100 can be prevented from being broken or damaged.

In the maximum compression step, the lower end of the interference member 20 does not make contact with the guide housing 30. In the maximum compression step, the distance from the lower end of the interference member 20 to the upper surface of the guide housing 30 is referred to as a fourth separation distance D4. In other words, even when the terminal 85 of the semiconductor package 80 is further lowered beyond the stroke limit value until the electro-conductive contact pin 100 is compressed to the maximum extent, the fourth separation distance D4 is formed so that the interference member 20 does not make contact with the guide housing 30. The lower end of the interference member 20 is located apart from the upper surface of the guide housing 30 by the fourth separation distance D4. Here, the fourth separation distance D4 may be 10 μm.

The elastic portion 150 is formed by alternately connecting the plurality of straight portions 153 and the plurality of curved portions 154. In the maximum compression step, the straight portions 153 adjacent in the upper and lower directions do not make contact with each other. In other words, even when the terminal 85 of the semiconductor package 80 is further lowered beyond the stroke limit value until the electro-conductive contact pin 100 is compressed to the maximum extent, the straight portions 153 adjacent in the upper and lower directions do not make contact with each In the maximum other. In the maximum compression step, since the lower end of the interference member 20 is spaced apart from the upper surface of the guide housing 30 by the fourth separation distance D4, the straight portions 153 adjacent in the upper and lower directions do not make contact with each other within the fourth separation distance D4. That is, the maximum compression step is a step in which the first connection portion 110 and the second connection portion 120 are allowed to be displaced to the maximum extent, and is not a step in which the elastic portion 150 is compressed to the maximum extent. When the first connection portion 110 and the second connection portion 120 reach a point where they are no longer allowed to be displaced, the elastic portion 150 is in a state where it is allowed to be further compressed because the straight portions 153 adjacent in the upper and lower directions are spaced apart from each other. With this, the elastic portion 150 can be prevented from being excessively compressed and damaged even when the electro-conductive contact pin 100 is compressed to the maximum extent.

When a part of the guide housing 30 corresponding to a lower part of the interference member 20 is thinned or a part of the guide housing 30 corresponding to the lower part of the interference member 20 is cut and removed away, a problem occurs in that the strength of the guide housing 30 is partially weakened. However, according to the preferred embodiment of the present disclosure, since the guide housing 30 is formed with a uniform overall thickness including a part corresponding to the position of the interference member 20, the guide housing 30 can be prevented from locally damaged or broken. As described above, according to the preferred embodiment of the present disclosure, it is possible to prevent the guide housing 30 and/or the electro-conductive contact pin 100 from being damaged by the interference member 20 protruding downward from the terminal 85 while preventing local damage or breakage of the guide housing 30.

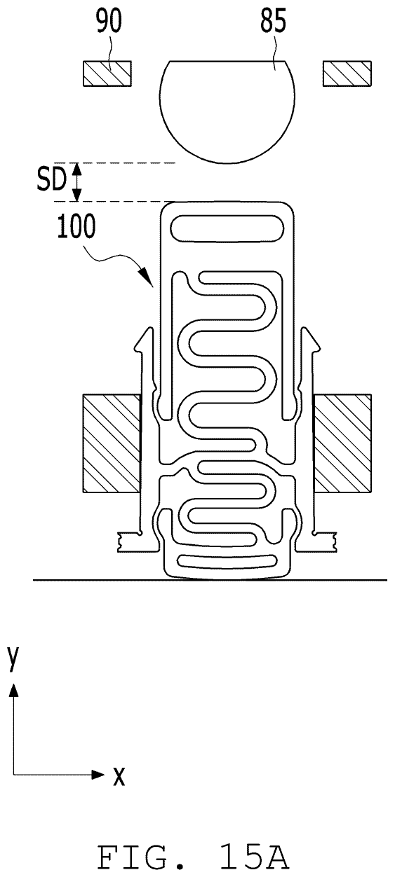

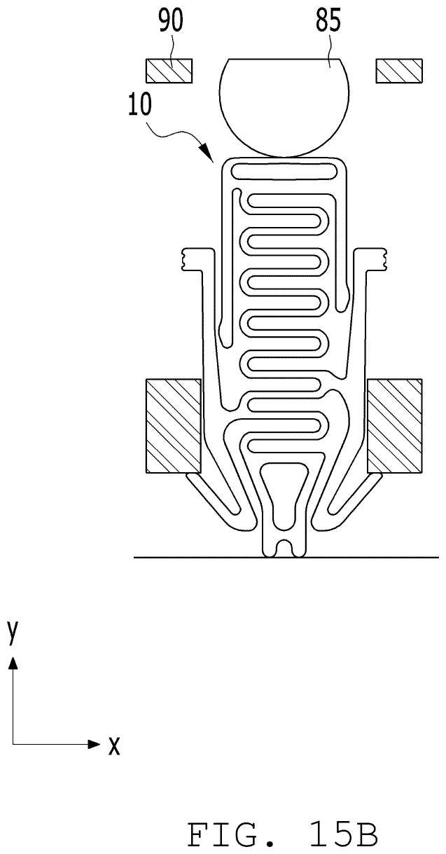

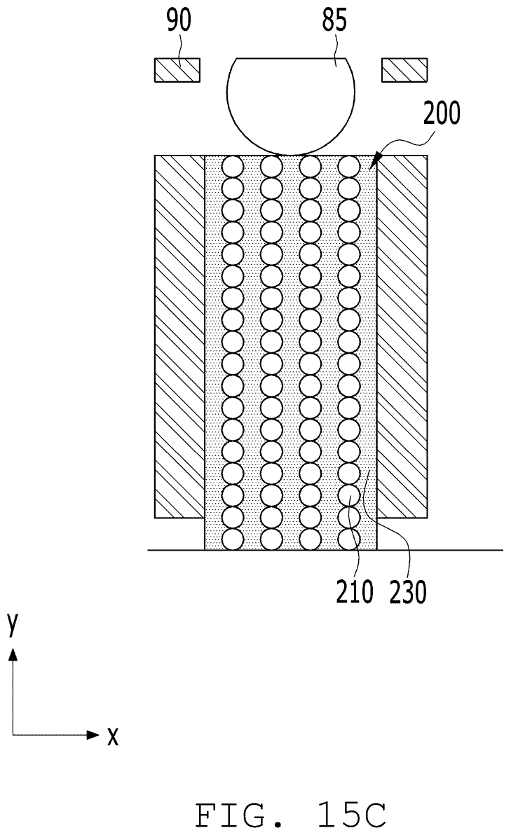

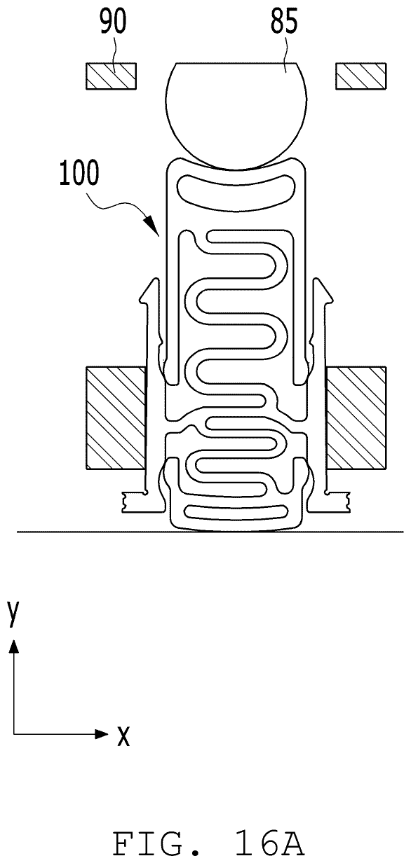

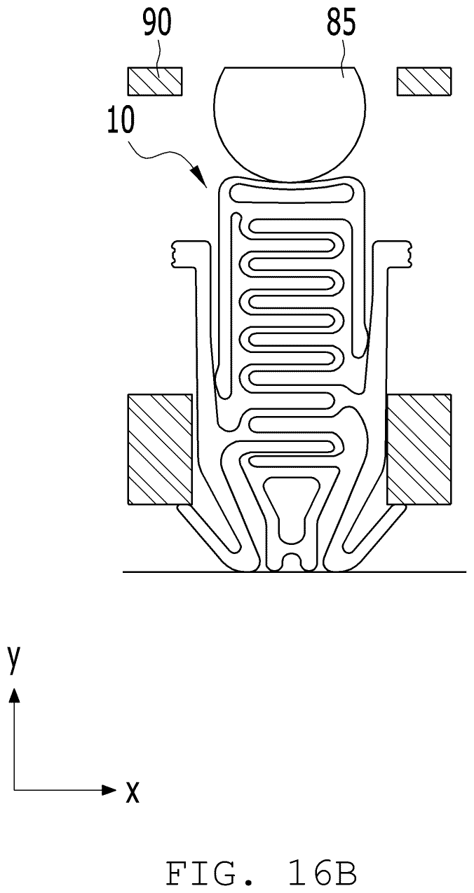

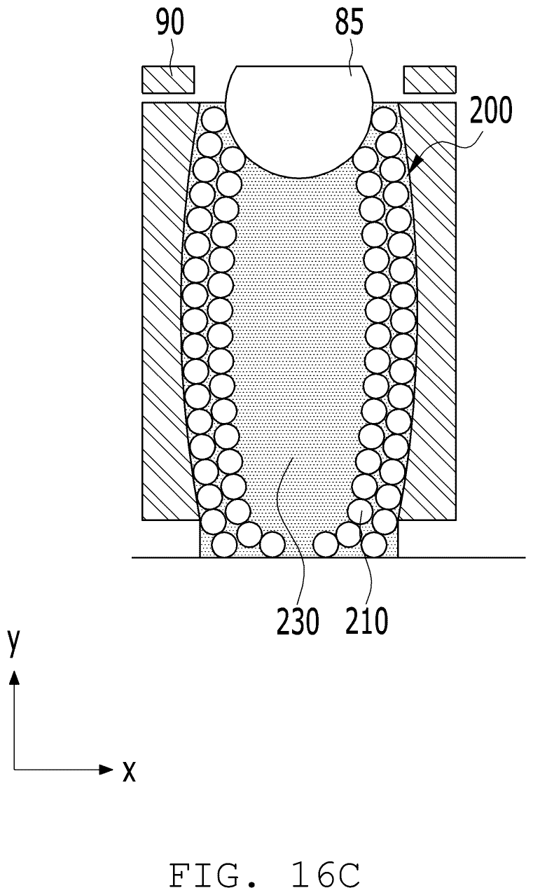

FIGS. 15A to 15C are views illustrating a comparison of the pre-pusher pressurization step before the semiconductor package is seated on the insert and then pressurized by the pusher between the preferred embodiment of the present disclosure, the technology served as the background for the present disclosure, and a conventional rubber-type test socket, in which FIG. 15A is a view illustrating the preferred embodiment of the present disclosure, FIG. 15B is a view illustrating the technology served as the background for the present disclosure, and FIG. 15C is a view illustrating the conventional rubber-type test socket. FIGS. 16A to 16C are views illustrating a comparison of the stroke completion step in which the semiconductor package is lowered to the stroke limit value by pressurization of the pusher between the preferred embodiment of the present disclosure, the technology served as the background for the present disclosure, and the conventional rubber-type test socket, in which FIG. 16A is a view illustrating the preferred embodiment of the present disclosure, FIG. 16B is a view illustrating the technology served as the background for the present disclosure, and FIG. 16C is a view illustrating the conventional rubber-type test socket.

In the case of the conventional rubber-type test socket, when the semiconductor package 80 is seated on the insert film 90, the terminal 85 of the semiconductor package 80 is brought into contact with an upper surface of a conductive portion 200. The conductive portion 200 includes conductive particles 210 and an elastic material 230. The elastic material 220 is formed integrally with the conductive particles 210 to form the conductive portion 200. The elastic material 230 may be a cured silicone rubber. Since the conventional rubber-type test socket needs to be formed with a contact resistance of equal to or less than 200 m ohm, each conductive portion 200 is pressurized with a force of 10 g and a stroke of 100 μm. That is, the conventional rubber-type test socket is designed to achieve a low contact resistance by setting a stroke limit value to 100 μm.

The related-art technology that is served as the background for the present disclosure is to replace the conductive portion 200 with an MEMS pin in the conventional rubber-type test socket. Unlike the conductive portion 200 composed of the conductive particles 210 and the elastic material 220, testing is conducted under the same conditions as the rubber-type test socket even though the MEMS pin is adopted. That is, in the pre-pusher pressurization step, the terminal 85 of the semiconductor package 80 is in contact with the upper surface of the electro-conductive contact pin 100. In this state, when the semiconductor package 80 is pressurized to the stroke limit value of 100 μm, excessive stress is applied to the semiconductor package. In addition, in this state, there is a high risk that the guide housing 30 and/or the electro-conductive contact pin 100 may be damaged or broken by the interference member 20.

On the contrary, in the case of the preferred embodiment of the present disclosure, when the semiconductor package 80 is seated on the insert film 90, the terminal of the semiconductor package 80 is spaced apart from the upper surface of the electro-conductive contact pin 100 by a separation distance SD. The separation distance SD is a dimension smaller than the stroke limit value, and may be in the range of 40% to 60% of the stroke limit value. Preferably, the separation distance SD is 50 pm. In the pre-pusher pressurization step, by making the terminal 85 of the semiconductor package 80 spaced apart from the electro-conductive contact pin 100 by the separation distance SD, the electro-conductive contact pin 100 can be prevented from being excessively compressed during a stroke process. In addition, by making the separation distance SD smaller than the stroke limit value, the terminal 85 is brought into contact with the electro-conductive contact pin 100 while the semiconductor package 80 is lowered.

Unlike a rubber-type pin that needs to be pressurized to the stroke limit value to obtain a desired contact resistance, an MEMS-type pin does not require excessive stroke because a current path is formed simply by making contact of the terminal 85 of the semiconductor package 80 with the electro-conductive contact pin 100. Therefore, by securing the separation distance SD, it is possible to prevent the electro-conductive contact pin 100 from being excessively compressed, and also secure a non-interference section of the interference member 20 corresponding to the separation distance SD.

When the length of the conductive portion 200 of the conventional rubber-type test socket is 450 μm, the overall length of an electro-conductive contact pin 10 of the related-art technology served as the background for the present disclosure is 450 μm, the overall length L of the electro-conductive contact pin 100 according to the preferred embodiment of the present disclosure is 400 μm, and the stroke limit value is 100 μm, the compression ratio (=before compression/after compression) of the conductive portion 200 of the conventional rubber-type test socket and the electro-conductive contact pin 10 of the related-art technology served as the background for the present disclosure is 128%, whereas the compression ratio of the electro-conductive contact pin 100 according to the preferred embodiment of the present disclosure is 114%. According to the preferred embodiment of the present disclosure as described above, the electro-conductive contact pin 100 is not subjected to excessive compressive stress, thereby improving durability.

The electro-conductive contact pin 100 according to the preferred embodiment of the present disclosure described above is provided in the inspection device 11 and is used to transmit electrical signals by making electrical and physical contact with the inspection object.

The inspection device 11 may be an inspection device used in a semiconductor manufacturing process, for example, The electro-conductive a probe card or a test socket. contact pin 100 may be an electro-conductive contact pin provided in the probe card for inspecting a semiconductor chip, or may be a socket pin provided in the test socket for inspecting a semiconductor package and inspecting the semiconductor package. However, the inspection device 11 that can use the electro-conductive contact pin 100 according to the preferred embodiment of the present disclosure is not limited thereto and includes any inspection device for checking whether the inspection object is defective by applying electricity.

The inspection object 80 of the inspection device 11 may include a semiconductor device, a memory chip, a microprocessor chip, a logic chip, a light-emitting device, or a combination thereof. For example, the inspection object includes a logic LSI (such as an ASIC, an FPGA, and an ASSP), a microprocessor (such as a CPU and a GPU), a memory (such as a DRAM and a hybrid memory cube (HMC), a magnetic RAM (MRAM), a phase-change memory (PCM), a resistive RAM (ReRAM), a ferroelectric RAM (FeRAM), a flash memory (such as NAND flash), a semiconductor light-emitting device (such as an LED, a mini LED, and a micro-LED), a power device, an analog IC (such as a DC-AC converter and an insulating gate bipolar transistor (IGBT)), an MEMS (such as an acceleration sensor, a pressure sensor, a vibrator, and a gyro sensor), a wireless device (such as a GPS, an FM, an NFC, an RFEM, an MMIC, and a WLAN), a discrete device, a BSI, a CIS, a camera module, a CMOS, a passive device, a GAW filter, an RF filter, an RF IPD, an APE, and a BB.

Although the preferred embodiments of the present disclosure have been disclosed for illustrative purposes, those skilled in the art will appreciate that various modifications, additions, and substitutions are possible, without departing from the scope and spirit of the present disclosure as disclosed in the accompanying claims.

### DESCRIPTION OF THE REFERENCE NUMERALS IN THE DRAWINGS

11: inspection device
100: electro-conductive contact pin
110: first connection portion
120: second connection portion
130: support portion
140: connecting portion
150: elastic portion

1. An inspection device, comprising:
an insert having a receiving portion configured to receive a semiconductor package;
an interference member provided at a lower part of the insert, and protruding further downward than a terminal of the semiconductor package while the semiconductor package is received in the receiving portion of the insert;
a guide housing formed with a uniform overall thickness including a part corresponding to a position of the interference member; and
an electro-conductive contact pin installed in the guide housing,
wherein a protrusion length of the electro-conductive contact pin protruding upward from an upper surface of the guide housing is longer than a protrusion length of the interference member protruding downward from a lower end of the terminal.

2. The inspection device of claim 1, wherein in a stroke completion step where the terminal of the semiconductor package is further lowered to a stroke limit value after contact with the electro-conductive contact pin, a third separation distance is formed so that the interference member does not make contact with the guide housing.

3. The inspection device of claim 1, wherein in a stroke completion step where the terminal of the semiconductor package is further lowered to a stroke limit value after contact with the electro-conductive contact pin, the electro-conductive contact pin is allowed to be further compressed even when the interference member is brought into contact with the guide housing.

4. The inspection device of claim 1, wherein the electro-conductive contact pin comprises:
a first connection portion connected to the terminal of the semiconductor package;
a second connection portion connected to a circuit board;
a support portion facing an inner wall of the guide housing and extending in a length direction;
an elastic portion connected to at least one of the first connection portion and the second connection portion and configured to be elastically deformable along the length direction; and
a connecting portion connecting the elastic portion to the support portion.

5. The inspection device of claim 4, wherein the first connection portion comprises:
a first contact portion configured to be brought into contact with the terminal; and
a first flange extending downward from the first contact portion and provided between the elastic portion and the support portion.

6. The inspection device of claim 5, wherein the first flange is brought into contact with an inner surface of the support portion as the elastic portion is compressed, thereby forming a current path.

7. The inspection device of claim 5, wherein the support portion comprises:
a first support portion located at a first side of the electro-conductive contact pin; and
a second support portion located at a second side of the electro-conductive contact pin,
wherein a dimension of the first contact portion in a width direction is smaller than a dimension between the first support portion and the second support portion, and
the first flange is located within a region between the first support portion and the second support portion.

8. An inspection device, comprising:
an insert having a receiving portion configured to receive a semiconductor package;
an interference member protruding further downward than a terminal of the semiconductor package while the semiconductor package is received in the receiving portion of the insert;
a guide housing formed with a uniform overall thickness including a part corresponding to a position of the interference member; and
an electro-conductive contact pin installed in the guide housing,
wherein in a pre-pusher pressurization step before pressurizing the semiconductor package toward the electro-conductive contact pin, the terminal of the semiconductor package does not make contact with the electro-conductive contact pin.

9. The inspection device of claim 8, wherein in a contact step where the semiconductor package is pressurized toward the electro-conductive contact pin so that the terminal of the semiconductor package is brought into contact with the electro-conductive contact pin, a second separation distance is formed so that the interference member does not make contact with the guide housing.

10. The inspection device of claim 8, wherein in a stroke completion step where the terminal of the semiconductor package is further lowered to a stroke limit value after contact with the electro-conductive contact pin, a third separation distance is formed so that the interference member does not make contact with the guide housing.

11. The inspection device of claim 8, wherein in a stroke completion step where the terminal of the semiconductor package is further lowered to a stroke limit value after contact with the electro-conductive contact pin, a third separation distance is formed so that the interference member does not make contact with the guide housing,
wherein a difference between a first separation distance and the third separation distance corresponds to the set stroke limit value.

12. The inspection device of claim 8, wherein even when the terminal of the semiconductor package is further lowered beyond the stroke limit value until the electro-conductive contact pin is compressed to a maximum extent, a fourth separation distance is formed so that the interference member does not make contact with the guide housing.

13. The inspection device of claim 12, wherein the electro-conductive contact pin comprises an elastic portion formed by alternately connecting a plurality of straight portions and a plurality of curved portions,
wherein even when the terminal of the semiconductor package is further lowered beyond the stroke limit value until the electro-conductive contact pin is compressed to the maximum extent, the straight portions adjacent in upper and lower directions do not make contact with each other.

14. (canceled)

15. (canceled)

16. (canceled)

17. An inspection device, comprising:
a guide housing formed with a uniform overall thickness; and
an electro-conductive contact pin installed in the guide housing,
wherein the electro-conductive contact pin comprises:
a first connection portion connected to a terminal of a semiconductor package;
a second connection portion connected to a circuit board;
a support portion facing an inner wall of the guide housing and extending in a length direction;
an elastic portion connected to at least one of the first connection portion and the second connection portion and configured to be elastically deformable along the length direction; and
a connecting portion connecting the elastic portion to the support portion,
wherein a protrusion length of the first connection portion protruding from an upper surface of the guide housing is longer than a protrusion of the second connection portion protruding from a lower surface of the guide housing,
the first connection portion and the second connection portion are displaceable in a vertical direction, wherein a displacement range of the first connection portion is longer than that of the second connection portion, and
at least one of the first connection portion and the second connection portion is brought into contact with the support portion during displacement to form a current path.

18. The inspection device of claim 17, wherein the guide housing is made of a polyimide material.

19. The inspection device of claim 17, wherein the first connection portion comprises:
a first contact portion configured to be brought into contact with the terminal; and
a first flange extending downward from the first contact portion and provided between the elastic portion and the support portion,
wherein downward displacement of the first flange causes a lower end of the first flange to be brought into contact with the connecting portion, thereby stopping further downward movement of the first contact portion.
